(19) United States
(12) Patent Application Publication
(10) Pub. No.: US 2026/0333710 A1
(43) Pub. Date: Oct. 22, 2026

(54) SEMICONDUCTOR STRUCTURES AND METHODS OF FORMING THE SAME

(71) Applicant: TAIWAN SEMICONDUCTOR MANUFACTURING COMPANY LTD., HSINCHU (TW)

(72) Inventors: YONG-JIE WU, TAINAN CITY (TW); YEN-CHUNG HO, HSINCHU (TW); KATHERINE H. CHIANG, NEW TAIPEI CITY (TW)

(21) Appl. No.: 19/181,380

(22) Filed: Apr. 17, 2025

(51) Int. Cl. H10B 63/00

(52) U.S. Cl. CPC H10B 63/30; H10B 63/80

(57) ABSTRACT

A method of forming a semiconductor structure is provided. The method includes forming a first TFT and a second TFT of a memory structure over a substrate. Each of the first TFT and the second TFT includes a gate stack over the substrate, a channel layer on the gate stack, a dielectric layer on the channel layer, a hydrogen blocking layer buried in the middle of the dielectric layer, source/drain features formed in the dielectric layer and in contact with the channel layer. The hydrogen blocking layers of the first TFT and the second TFT are positioned at different levels. The method further includes forming a memory cell on each of the first TFT and the second TFT, and the memory cell is coupled to the one of the first TFT and the second TFT.

### BACKGROUND

In the semiconductor industry, there is a constant desire to increase the integration density of integrated circuits. To do so, individual elements or components have become increasingly smaller. In addition, moving peripheral transistors from the front-end-of-line (FEOL) to the back-end-of-line (BEOL) of fabrication may be advantageous because functionality may be added at the BEOL while valuable chip area may be made available in the FEOL. Transistors such as thin film transistors (TFTs) are considered promising candidates for BEOL control elements in memory devices. A TFT structure that has a channel layer made of oxide semiconductor can be scaled down for the application of high-density memory arrays.

Transistors (such as TFTs) with channels made of oxide semiconductors are an attractive option as selectors in memory devices for BEOL integration due to their low leakage behavior. However, the transistors may suffer from low on-currents. In addition, the transistors fabricated on a substrate (e.g., a wafer) may exhibit the same electrical characteristics, such as identical threshold voltage (Vt). Therefore, these transistors with the same Vt limit the potential for integration of logic devices.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of an exemplary semiconductor structure prior to formation of an array of memory structures, in accordance with some embodiments of the present disclosure.

FIG. 2 is a cross-sectional view of an exemplary semiconductor structure during formation of an array of memory structures, in accordance with some embodiments of the present disclosure.

FIG. 3 is a cross-sectional view of an exemplary semiconductor structure after the formation of upper-level metal interconnect structures.

FIGS. 4, 5, 6, 7, 8, 9, 10, 11, 12 and 13 are fragmentary cross-sectional views illustrating a method of forming memory structures at various intermediate stages, in accordance with some embodiments of the present disclosure.

FIG. 14 is a flowchart illustrating a method for forming memory structures according to an embodiment of the present disclosure.

FIG. 15 is a graph showing the results of evaluating gate voltage-drain current characteristics of a low-Vt device and a high-Vt device.

FIG. 16 is a cross-sectional view of an exemplary semiconductor structure with upper-level metal interconnect structures, including an array of memory structures, in accordance with some embodiments of the present disclosure.

FIGS. 17, 18, 19, 20, 21, 22, 23, 24, 25, 26, 27 and 28 are fragmentary cross-sectional views illustrating a method of forming memory structures at various intermediate stages, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, a source/drain feature as used herein may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the like thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure is generally related to semiconductor structures and methods of forming the same. In some embodiments, a semiconductor structures includes an array of memory structures. Each of the memory structures may include a transistor (such as a TFT) and a memory cell formed on and coupled to the transistor (e.g., a TFT). Transistors with different threshold voltages can be simultaneously fabricated on a wafer, using the methods provided in some embodiments. Several memory cells of different types can be selected by suitable TFTs with different threshold voltages, which enhance selector application.

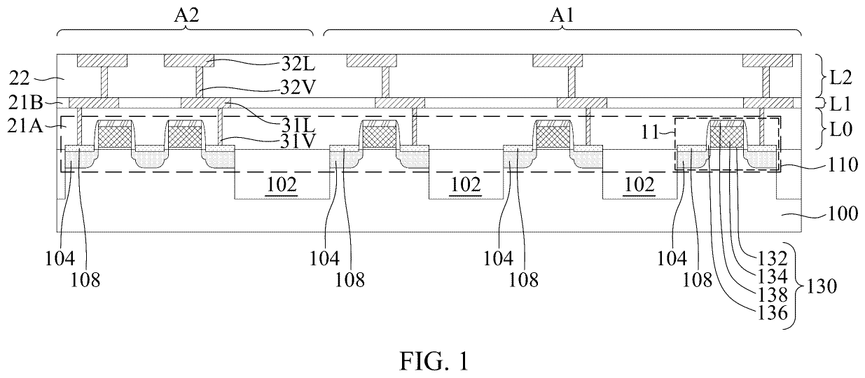

The various aspects of the present disclosure will now be described in more detail with reference to the figures. FIG. 1 is a cross-sectional view of an exemplary semiconductor structure prior to formation of an array of memory structures, in accordance with some embodiments of the present disclosure.

The exemplary semiconductor structure includes a substrate 100. The substrate 100 may include a bulk semiconductor substrate such as a silicon substrate in which the semiconductor material layer continuously extends from a top surface of the substrate 100 to a bottom surface of the substrate 100, or a semiconductor-on-insulator layer including the semiconductor material layer as a top semiconductor layer overlying a buried insulator layer (such as a silicon oxide layer). The exemplary semiconductor structure may include various device regions, which may include a memory array region A1 in which at least one array of non-volatile memory cells or volatile memory cells may be subsequently formed. The exemplary semiconductor structure may also include a peripheral logic region A2 in which electrical connections between each array of memory cells and a peripheral circuit including field effect transistors may be subsequently formed. Areas of the memory array region A1 and the peripheral logic region A2 may be employed to form various elements of the peripheral circuit.

Semiconductor devices such as field effect transistors (FETs) may be formed on and/or in the semiconductor material layer during a front-end-of-line (FEOL) fabrication process. For example, shallow trench isolation structures 102 may be formed in an upper portion of the semiconductor material layer of the substrate 100 by forming shallow trenches and subsequently filling the shallow trenches with a dielectric material such as silicon oxide. Other suitable dielectric materials are within the scope of disclosure. Various doped wells (not expressly shown) may be formed in various regions of the upper portion of the semiconductor material layer by performing masked ion implantation processes.

In some embodiments, gate structures 130 are formed over the top surface of the substrate 100 by depositing and patterning a gate dielectric layer, a gate electrode layer, and a gate cap dielectric layer. Each of the gate structures 130 may include a vertical stack of a gate dielectric 132, a gate electrode 134, and a gate cap dielectric 138, which is herein referred to as a gate stack (132, 134, and 138). Ion implantation processes may be performed to form extension implant regions, which may include source extension regions and drain extension regions. Gate spacers 136 may be formed at sidewalls of the gate stacks (132, 134, and 138). A gate stack (132, 134, and 138) and a gate spacer 136 constitute a gate structure 130. Additional ion implantation processes may be performed that use the gate structures 130 as self-aligned implantation masks to form active regions. Such active regions may include source regions and drain regions. Upper portions of the active regions may overlap with portions of the extension implantation regions. Each combination of an extension implantation region and an active region may constitute an active region 104, which may be a source region or a drain region depending on electrical biasing. A semiconductor channel 105 may be formed underneath each of the gate stacks (132, 134, and 138) between a neighboring pair of active regions 104. Metal-semiconductor alloy regions 108 may be formed on the top surfaces of the active regions 104.

In embodiments in which an array of memory structures is subsequently formed at a level of a dielectric layer (e.g., a third interconnect dielectric layer 23 described later) on a FEOL structure, field effect transistors (FET) 11 may be formed on the semiconductor material layer, and may include a circuit that provides functions that operate memory cells of the memory structures. In addition, devices in the peripheral logic region A2 may be configured to control the programming operation, the erase operation, and the sensing (read) operation of the memory cells. For example, the devices in the peripheral logic region A2 may include sensing circuitry and/or programming circuitry. Complementary metal-oxide-semiconductor (CMOS) transistors may be provided on the semiconductor material layer, which may include a periphery circuit for the array(s) of TFTs to be subsequently formed. CMOS transistors and optionally additional semiconductor devices (such as resistors, diodes, capacitors, etc.) are collectively referred to as CMOS circuitry 110.

One or more of the field effect transistors 11 in the CMOS circuitry 110 may be formed on the semiconductor material layer. Each of the field effect transistors 11 may include a gate structure 130, a semiconductor channel 105, a pair of active regions 104 (one of which functions as a source region and another of which functions as a drain region), and optional metal-semiconductor alloy regions 108. In some embodiments, several field effect transistors 11 in the CMOS circuitry 110 may include a respective node that is subsequently electrically connected to a node of a respective memory cell to be subsequently formed. For example, one of the field effect transistors 11 in the CMOS circuitry 110 includes active regions 104. One of these active regions 104 functions as either a source electrode or a drain electrode, which is electrically connected to a node of a respective memory cell formed subsequently.

Various interconnect-level structures may be subsequently formed, which are created prior to formation of an array of memory structures, and are herein referred to as lower interconnect-level structures (L0, L1, L2). Structures (e.g., FETs) on the substrate 100 and the lower interconnect-level structures (L0, L1, L2) can be referred to as a FEOL structure. In the case that a two-dimensional array of the memory structures is to be subsequently formed over two levels of interconnect-level metal lines, the lower interconnect-level structures (L0, L1, L2) may include a contact-level structure L0, a first interconnect-level structure L1, and a second interconnect-level structure L2.

The contact-level structure L0 may include a planarization dielectric layer 21A including a planarizable dielectric material such as silicon oxide and various contact via structures 31V contacting a respective one of the active regions 104 or the gate electrodes 134 and formed within the planarization dielectric layer 21A. The first interconnect-level structure L1 includes a first interconnect dielectric layer 21B and first metal lines 31L formed within the first interconnect dielectric layer 21B. The first interconnect dielectric layer 21B is also referred to as a first line-level dielectric layer. The first metal lines 31L may contact a respective one of the contact via structures 31V. The second interconnect-level structure L2 includes a second interconnect dielectric layer 22, which may include a stack of a first via-level dielectric material layer and a second line-level dielectric material layer or a line-and-via-level dielectric material layer. The second interconnect dielectric layer 22 may have formed in second interconnect-level metal interconnect structures (32V, 32L), which include first metal via structures 32V and second metal lines 32L. Top surfaces of the second metal lines 32L may be coplanar with the top surface of the second interconnect dielectric layer 22.

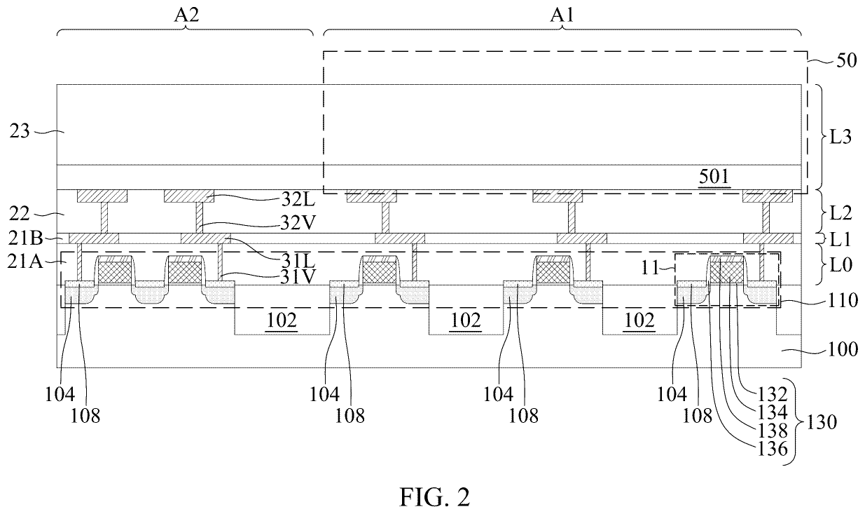

FIG. 2 is a cross-sectional view of an exemplary semiconductor structure during formation of an array of memory structures, in accordance with some embodiments of the present disclosure. In some embodiments, an array 50 of memory structures is formed in the memory array region A1 over the second interconnect-level structure L2. Each of the memory structures may include a thin-fin transistor (TFT) (such as a back gate TFT selector or any type of selector device) and a memory cell on the TFT. The details of the structures and the processing steps for the array 50 of memory structures are described in detail below. A third interconnect dielectric layer 23 may be formed during formation of the array 50 of memory structures. The set of all structures formed at the level of the transistors of the array 50 of memory structures is herein referred to as a third interconnect-level structure L3. The memory cells on the TFTs may be formed in a next level, and may be parts of a fourth interconnect-level structure L4.

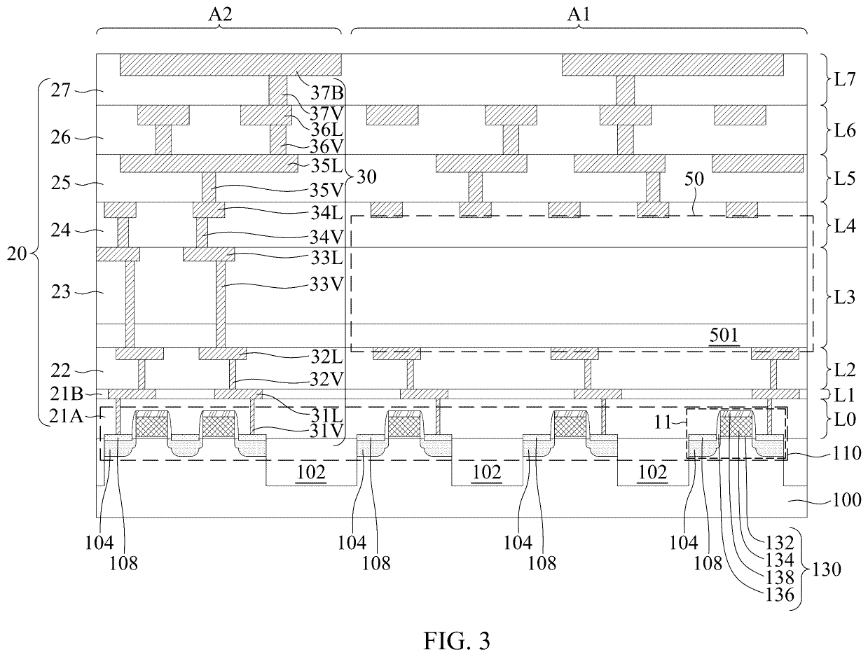

FIG. 3 is a cross-sectional view of an exemplary semiconductor structure after the formation of upper-level metal interconnect structures. Referring to FIG. 3, third interconnect-level metal interconnect structures (33V, 33L) may be formed in the third interconnect dielectric layer 23. The third interconnect-level metal interconnect structures (33V, 33L) may include second metal via structures 33V and third metal lines 33L. In some embodiments, additional interconnect-level structures are subsequently formed, which are herein referred to as upper interconnect-level structures (L4, L5, L6, L7). For example, the upper interconnect-level structures (L4, L5, L6, L7) may include a fourth interconnect-level structure L4, a fifth interconnect-level structure L5, a sixth interconnect-level structure L6, and a seventh interconnect-level structure L7. The fourth interconnect-level structure L4 may include a fourth interconnect dielectric layer 24 having formed therein fourth interconnect-level metal interconnect structures (34V, 34L), which may include third metal via structures 34V and fourth metal lines 34L. The fifth interconnect-level structure L5 may include a fifth interconnect dielectric layer 25 having formed therein fifth interconnect-level metal interconnect structures (35V, 35L), which may include fourth metal via structures 35V and fifth metal lines 35L. The sixth interconnect-level structure L6 may include a sixth interconnect dielectric layer 26 having formed therein sixth interconnect-level metal interconnect structures (36V, 36L), which may include fifth metal via structures 36V and sixth metal lines 36L. The seventh interconnect-level structure L7 may include a seventh interconnect dielectric layer 27 having formed therein sixth metal via structures 37V (which are seventh interconnect-level metal interconnect structures) and metal bonding pads 37B. The metal bonding pads 37B may be configured for solder bonding (which may employ C4 ball bonding or wire bonding), or may be configured for metal-to-metal bonding (such as copper-to-copper bonding). It should be noted that although four interconnect-level structures (L4, L5, L6, L7) are formed over an array of TFTs in this exemplified embodiment, the disclosure is not limited thereto. An interconnect structure that includes other numbers of interconnect-level structures can be formed above the TFTs.

Each interconnect dielectric layer may be referred to as an interconnect dielectric layer (ILD) layer 20. Each interconnect-level metal interconnect structure may be referred to as a metal interconnect structure 30. Each contiguous combination of a metal via structure and an overlying metal line located within a same interconnect-level structure (L2-L7) may be formed sequentially as two distinct structures by employing two single damascene processes, or may be simultaneously formed as a unitary structure employing a dual damascene process. Each of the metal interconnect structures 30 may include a respective metallic liner (such as a layer of TiN, TaN, or WN having a thickness in a range from 2 nm to 20 nm) and a respective metallic fill material (such as W, Cu, Co, Mo, Ru, another elemental metal, or an alloy or a combination thereof). Other suitable materials for use as a metallic liner and metallic fill material are within the contemplated scope of disclosure. Various etch stop dielectric layers and dielectric capping layers may be inserted between vertically neighboring pairs of ILD layers 20, or may be incorporated into one or more of the ILD layers 20.

While the present disclosure is described employing an embodiment in which the transistors of the array 50 of memory structures are formed as components of a third interconnect-level structure L3, embodiments are expressly contemplated herein in which the transistors of the array 50 of memory structures are formed as components of any other interconnect-level structure (e.g., L1-L7). Further, while the present disclosure is described using an embodiment in which a set of eight interconnect-level structures is formed, embodiments are expressly contemplated herein in which a different number of interconnect-level structures is used. In addition, embodiments are expressly contemplated herein in which two or more arrays 50 of memory structures may be provided within multiple interconnect-level structures in the memory array region A1. While the present disclosure is described employing an embodiment in which an array 50 of memory structures is formed over two vertically adjoining interconnect-level structures, embodiments are expressly contemplated herein in which an array 50 of memory structures may be formed in a single interconnect-level structure.

In some embodiments, an array 50 of memory structures includes several memory structures. Each of the memory structures may include a transistor (such as a thin-fin transistor (TFT)) and a memory cell on the transistor. The transistor may act as a selector for the memory cell formed thereon. In some embodiments, the transistors of two memory structures of the array 50 have different structural configurations which are suitable for the memory cells with different threshold voltages. According to the method of the embodiments, the transistors of the array 50 of memory structures can be formed in the same interconnect-level structure, such as in the third interconnect-level structure L3, or in any other interconnect-level structure (e.g., L1-L7). The memory cells formed on the transistors may be formed in an interconnect-level structure (e.g., L4) adjacent to the interconnect-level structure (e.g., L3) in which the transistors of the embodiments are formed.

Thus, according to the embodiments, the transistors serving as selectors for the memory cells are moved from a FEOL structure to a BEOL structure, which provides several advantages for BEOL integration. For example, transistors such as TFTs may be processed at low temperature and can add functionality to the BEOL structure, while valuable chip area is made available in the FEOL structure. The Use of TFTs in the BEOL structure may serve as a scaling path for 3 nm node fabrication (N3) or beyond by relocating peripheral devices, such as power gates or Input/Output (I/O) devices, from the FEOL structure into higher metal levels of the BEOL structure. Relocating the TFTs from the FEOL structure to the BEOL structure may result in an area reduction of approximately 5% to 10% for a given device.

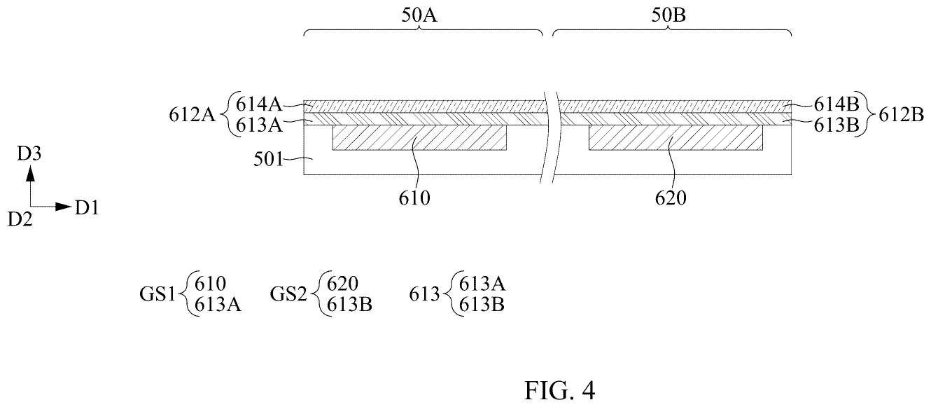

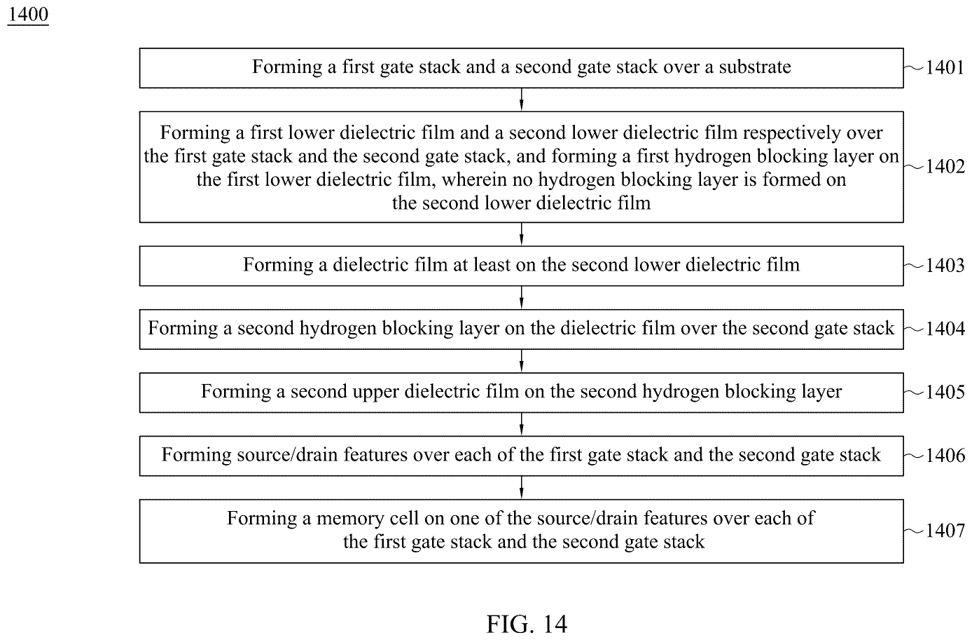

FIGS. 4-13 are fragmentary cross-sectional views illustrating a method of forming memory structures at various intermediate stages, in accordance with some embodiments of the present disclosure. FIG. 14 is a flowchart illustrating a method 1400 for forming memory structures according to an embodiment of the present disclosure.

Method 1400 is merely an example and is not intended to limit the present disclosure to what is explicitly illustrated in method 1400. Additional steps can be provided before, during, and after method 1400, and some steps described can be replaced, eliminated, or rearranged for additional embodiments of the method. Not all steps are described in detail herein for reasons of simplicity. In addition, the directions D1, D2 and D3 in FIGS. 4-13 are perpendicular to one another. Throughout the present disclosure, like reference numerals denote like features, unless otherwise specified.

Referring to FIG. 4 and FIG. 14, method 1400 includes a block 1401 where a first gate stack GS1 and a second gate stack GS2 are formed over a substrate (e.g., the substrate 100 in FIGS. 1-3), and a channel layer 614 is formed on each of the first gate stack GS1 and the second gate stack GS2.

In some embodiments, an insulating material layer 501 is formed over the substrate. The insulating material layer 501 may include a dielectric material such as silicon oxide (SiO₂), undoped silicate glass, a doped silicate glass, organosilicate glass, amorphous fluorinated carbon, porous variants thereof, or combinations thereof. The insulating material layer 501 may be deposited through any of a number of suitable deposition processes or grown over an interconnect-level structure, such as the second interconnect-level structure L2 or any other interconnect-level structure.

In some embodiments, the first gate stack GS1 is formed in the first region 50A of a memory array region A1 (FIGS. 1-3), and the second gate stack GS2 is formed in the second region 50B of the memory array region A1. The first gate stack GS1 may include a first gate electrode 610 and a first gate dielectric layer 613A on the first gate electrode 610. The second gate stack GS2 may include a second gate electrode 620 and the second gate dielectric layer 613B on the second gate electrode 620. In some embodiments, the first gate dielectric layer 613A is separated from the second gate dielectric layer 613B. In some embodiments, the first gate dielectric layer 613A extends from the first region 50A to the second region 50B, wherein the portion of the first gate dielectric layer 613A in the second region 50B is referred to as the second gate dielectric layer 613B. Herein, the first gate dielectric layer 613A and the second gate dielectric layer 613B may be collectively referred to as a gate dielectric layer 613.

The formation of the first gate electrode 610 and the second gate electrode 620 may include forming gate trenches in the insulating material layer 501, depositing a conductive material on the insulating material layer 501 and within the gate trenches, and removing excess amounts of the conductive material over the top surface of the insulating material layer 501. In some embodiments, the conductive material of the first gate electrode 610 and the second gate electrode 620 includes copper, aluminum, zirconium, titanium, titanium nitride, tungsten, tantalum, tantalum nitride, ruthenium, palladium, platinum, cobalt, nickel, iridium, alloys thereof, or the like. Other suitable electrically conductive materials are within the contemplated scope of this disclosure.

The conductive material of the first gate electrode 610 and the second gate electrode 620 may be deposited by a chemical vapor deposition (CVD) process, a physical vapor deposition (PVD) process, an atomic layer deposition (ALD) process, a sputtering process, laser ablation, or any suitable process. The CVD process may include a high density plasma CVD (HDPCVD) process, a metalorganic CVD (MOCVD) process, a plasma enhanced CVD (PECVD) process, or any suitable method.

A planarization process, such as a chemical mechanical polishing (CMP) process or the like, may then be performed to remove excess amounts of the conductive material from the top surface of the insulating material layer 501. After planarization, the top surface of the insulating material layer 501 is coplanar with the top surfaces of the first gate electrode 610 and the second gate electrode 620. The first gate electrode 610 and the second gate electrode 620 may extend parallel to one another (e.g., along the direction D2), and may be spaced apart according to the desired pitch between TFT devices.

In some embodiments, the first gate dielectric layer 613A and the second gate dielectric layer 613B are high-k dielectric layers, and can be formed by depositing any suitable high-k dielectric material using any suitable deposition process. The high-k dielectric layer may have a dielectric constant greater than 3.9. The first gate dielectric layer 613A and the second gate dielectric layer 613B may include, but are not limited to, silicon nitride, hafnium oxide (HfO₂), hafnium silicon oxide (HfSiO), hafnium tantalum oxide (HfTaO), hafnium titanium oxide (HfTiO), hafnium zirconium oxide (Hf_{0.5}Zr_{0.5}O₂) (HZO), tantalum oxide (Ta₂O₅), aluminum oxide (Al₂O₃), hafnium dioxide-alumina (HfO₂—Al₂O₃), zirconium oxide (ZrO₂), titanium oxide (TiO₂), strontium titanium oxide (SrTiO₃), or another suitable high-k dielectric material. Other suitable dielectric materials are within the scope of the present disclosure. In addition, each of the first gate dielectric layer 613A and the second gate dielectric layer 613B may have a thickness in the range of 0.5 nm to 5.0 nm, such as 1 nm to 4 nm, although greater or lesser thicknesses may be used.

In some embodiments, a first channel layer 614A is formed on the first (high-k) gate dielectric layer 613A, and a second channel layer 614B is formed on the second (high-k) gate dielectric layer 613B. The second channel layer 614B is separated from the first channel layer 614A. As shown in FIG. 4, in some embodiments, the first channel layer 614A is separated from the first gate electrode 610 by the first gate dielectric layer 613A, and the second channel layer 614B is separated from the second gate electrode 620 by the second gate dielectric layer 613B. The first channel layer 614A and the second channel layer 614B may be collectively or individually referred to as a channel layer 614 herein, for the sake of simplicity and clarity.

The first channel layer 614A and the second channel layer 614B may be formed by depositing any suitable semiconductor material, using any suitable deposition process. In some embodiments, the first channel layer 614A and the second channel layer 614B include polysilicon, amorphous silicon, or a semiconducting oxide, such as InGaZnO (IGZO), indium tin oxide (ITO), InWO, InZnO, InSnO, GaOx, InOx, or the like. Other suitable semiconductor materials are within the scope of the present disclosure.

In some embodiments, each of the memory structures may include a transistor (such as a TFT) and a memory cell on the transistor. The transistor may act as a selector for the memory cell formed thereon. Thus, the high-k gate dielectric layer and the channel layer on the high-k gate dielectric layer can be referred to as a selector layer. Therefore, the first gate dielectric layer 613A and the first channel layer 614A can be referred to as a first selector layer 612A. The second gate dielectric layer 613B and the second channel layer 614B can be referred to as a second selector layer 612B. Accordingly, in some embodiments, the first selector layer 612A is formed on the first gate electrode 610, and the second selector layer 612B is formed on the second gate electrode 620.

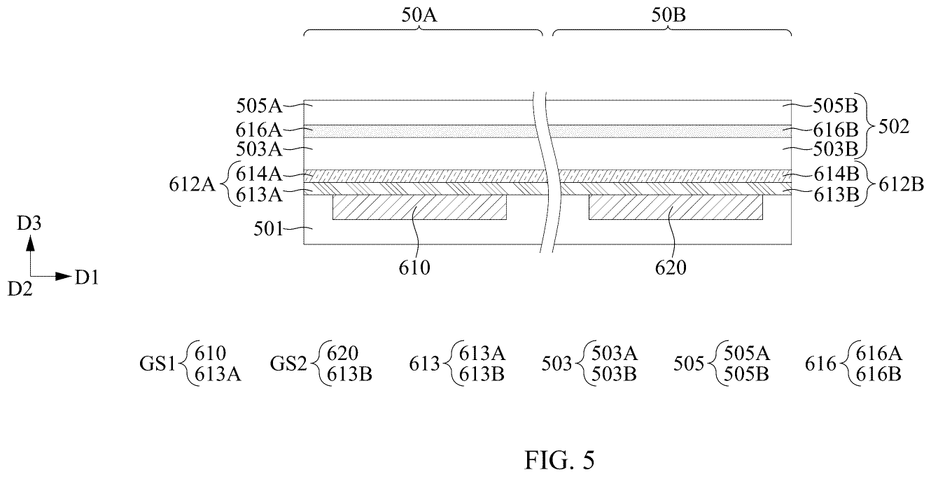

Referring to FIGS. 5-7 and FIG. 14, method 1400 includes a block 1402 where a first lower dielectric film and a second lower dielectric film are respectively formed over the first gate stack and the second gate stack, and a first hydrogen blocking layer is formed on the first lower dielectric film, wherein no hydrogen blocking layer is formed on the second lower dielectric film. Operation details of some embodiments are described below.

Referring to FIG. 5, in some embodiments, a dielectric 502 is formed on the channel layer 614 and extends over the first gate stack GS1 and the second gate stack GS2. A hydrogen blocking material layer 616 is buried in the middle of the dielectric 502 and extends over the first gate stack GS1 and the second gate stack GS2. As shown in FIG. 5, the hydrogen blocking material layer 616 is vertically separated from the channel layer 614. The dielectric 502 may include a first dielectric layer 503 on the channel layer 614, and a second dielectric layer 505 on the hydrogen blocking material layer 616. In some embodiments, the hydrogen blocking material layer 616 includes a first portion 616A in the first region 50A, and a second portion 616B in the second region 50B.

The formation of the dielectric 502 and the hydrogen blocking material layer 616 may include the operations described below. The first dielectric layer 503 that includes a first dielectric portion 503A in the first region 50A and a second dielectric portion 503B in the second region 50B may be deposited on the channel layer 614, using any suitable deposition method. Next, the hydrogen blocking material layer 616, which includes the first portion 616A in the first region 50A and the second portion 616B in the second region 50B, may be deposited on the first dielectric layer 503 using any suitable deposition method. Then, the second dielectric layer 505, which includes a first dielectric portion 505A in the first region 50A and a second dielectric portion 505B in the second region 50B, may be deposited on the hydrogen blocking material layer 616 using any suitable deposition method.

The first dielectric layer 503 and the second dielectric layer 505 may include a dielectric material such as silicon oxide or any suitable insulating material. For example, the first dielectric layer 503 and the second dielectric layer 505 include undoped silicate glass, a doped silicate glass, organosilicate glass, or a stack thereof. In some embodiments, the first dielectric layer 503 and the second dielectric layer 505 are formed of different dielectric materials. In some other embodiments, the first dielectric layer 503 and the second dielectric layer 505 are formed of the same dielectric material. Optionally, the first dielectric layer 503 may be planarized to provide a flat top surface. The second dielectric layer 505 may be planarized so that a planarized horizontal top surface of the second dielectric layer 505 is obtained. In some embodiments, the top surface of the first dielectric portion 505A is leveled with the top surface of the second dielectric portion 505B.

The hydrogen blocking material layer 616 may include a high-k dielectric material such as aluminum oxide (Al₂O₃), hafnium oxide (HfO₂), zirconium oxide (ZrO₂), or tantalum oxide (Ta₂O₅). In some embodiments, the hydrogen blocking material layer 616 includes aluminum oxide. For example, the hydrogen blocking material layer 616 can be an aluminum oxide layer. In some embodiments, the hydrogen blocking material layer 616 is a composite layer having multiple high-k dielectric sublayers or one high-k dielectric sublayer with one or more sublayers of other materials.

It is understood that the thickness of the hydrogen blocking material layer 616 can be sufficiently thick to prevent outgassing of hydrogen. In some embodiments, the thickness of the hydrogen blocking material layer 616 is between about 1 nm and about 100 nm, such as between 1 nm and 100 nm (such as 1 nm, 2 nm, 3 nm, 4 nm, 5 nm, 6 nm, 7 nm, 8 nm, 9 nm, 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, any of these values or in any range defined by any two of these values).

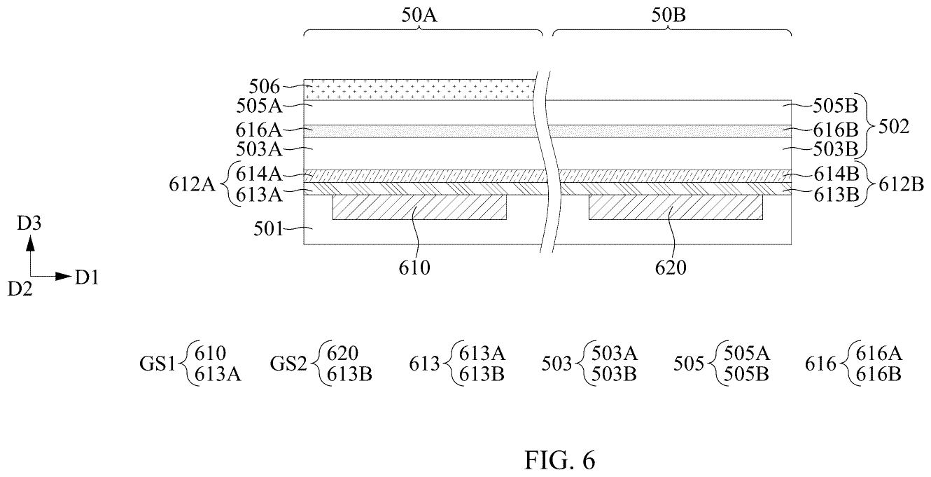

Referring to FIG. 6, a patterned photoresist layer 506 is formed on the dielectric 502 to cover the layers in the first region 50A and expose the layers in the second region 50B. In some embodiments, a photoresist material is deposited on the second dielectric layer 505 and is lithographically patterned to form the patterned photoresist layer 506. The patterned photoresist layer 506 covers the first dielectric portion 505A in the first region 50A and uncovers the second dielectric portion 505B in the second region 50B.

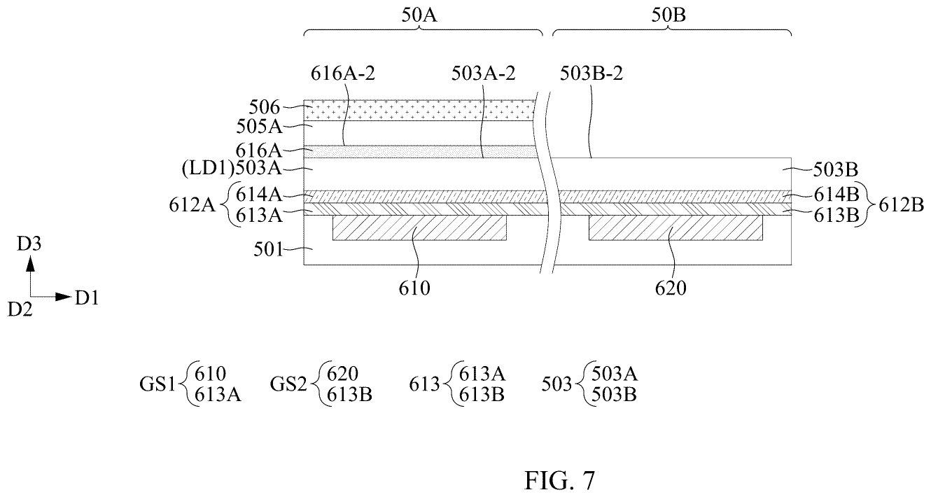

Next, referring to FIG. 7, in some embodiments, a portion of the dielectric 502 that is uncovered by the patterned photoresist layer 506, for example, the second dielectric portion 505B over the second gate stack GS2, is removed using any suitable process. For example, the second dielectric portion 505B is removed by etching, such as a dry etching process, a wet etching process, another suitable etching process, or a combination thereof. Next, in some embodiments, a portion of the hydrogen blocking material layer 616, such as the second portion 616B over the second gate stack GS2, is removed by any suitable process, using the patterned photoresist layer 506 as a mask. For example, the second portion 616B of the hydrogen blocking material layer 616 is removed by etching, such as a dry etching process, a wet etching process, another suitable etching process, or a combination thereof.

In some embodiments, as shown in FIG. 7, after the foregoing removal process, the first portion 616A of the hydrogen blocking material layer 616 remaining over the first gate stack GS1 can be referred to as the first hydrogen blocking layer in the first region 50A. Since the first portion 616A of the hydrogen blocking material layer 616 will be fabricated into the first hydrogen blocking layer, the first portion 616A may be referred to herein as the first hydrogen blocking layer 616A after the foregoing removal process.

In some embodiments, as shown in FIG. 7, after the foregoing removal process, the portion of the dielectric 502 that remains over the first gate stack GS1 and covered by the first hydrogen blocking layer 616A is referred to as a first lower dielectric film. Because the first dielectric portion 503A of the dielectric 502 is fabricated into the first lower dielectric film, the first dielectric portion 503A may be referred to herein as the first lower dielectric film 503A after the foregoing removal process.

In some embodiments, as shown in FIG. 7, after the foregoing removal process, the portion of the dielectric 502 remaining over the second gate stack GS2 can be referred to as a second lower dielectric film in the second region 50B. Since the second dielectric portion 503B will be fabricated into the second lower dielectric film, the second dielectric portion 503B can be referred to herein as the second lower dielectric film 503B in the second region 50B after the foregoing removal process.

In some embodiments, after the foregoing removal process, the top surface 503B-2 of the second lower dielectric film 503B in the second region 50B is substantially coplanar with the top surface 503A-2 of the first lower dielectric film 503A in the first region 50A. In some other embodiments, after the foregoing removal process, the top surface 503B-2 of the second lower dielectric film 503B is lower than the top surface 503A-2 of the first lower dielectric film 503A.

In some embodiments, after the second dielectric portion 505B and the second portion 616B of the hydrogen blocking material layer 616 are removed, the patterned photoresist layer 506 is removed using any suitable process. For example, the patterned photoresist layer 506 may be removed by a selective stripping process or an ashing process.

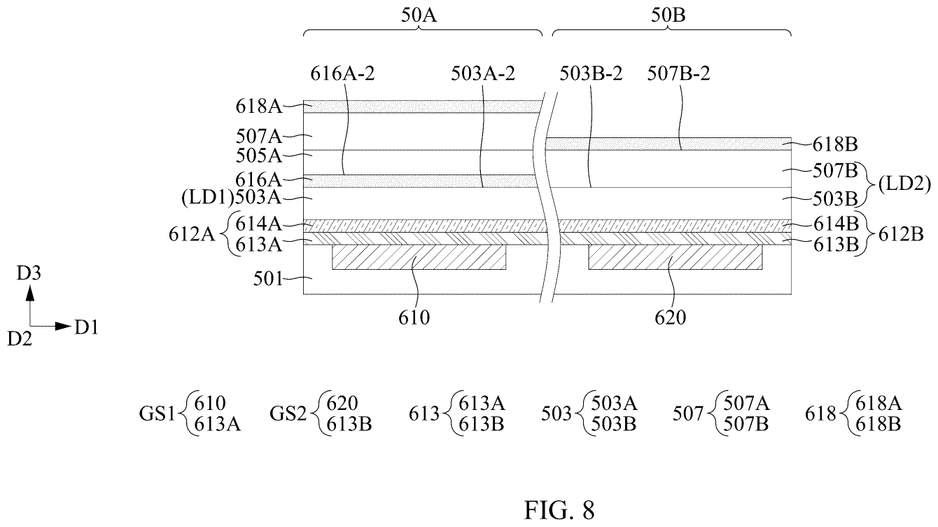

Referring to FIG. 8 and FIG. 14, method 1400 includes a block 1403 where a dielectric film 507 is formed at least on the second lower dielectric film 503B. In some embodiments, the dielectric film 507 includes a dielectric portion 507B on the second lower dielectric film 503B over the second gate stack GS2, and an extending dielectric portion 507A on the first dielectric portion 505A over the first gate stack GS1. In some embodiments, the top surface 507B-2 of the dielectric portion 507B in the second region 50B is above a level of the top surface 503A-2 of the first lower dielectric film 503A in the first region 50A. In some embodiments, the top surface 507B-2 of the dielectric portion 507B in the second region 50B is above a level of the top surface 616A-2 of the first hydrogen blocking layer 616A in the first region 50A.

In some embodiments, the dielectric film 507 may include silicon oxide or any suitable insulating material, such as undoped silicate glass, a doped silicate glass, organosilicate glass, or a stack thereof. The dielectric film 507 may be conformally deposited on the first dielectric portion 505A and the second lower dielectric film 503B using any suitable deposition method. The term “conformally” may be used herein for ease of description of a layer having substantially uniform thickness over various regions. The dielectric film 507 and the second dielectric layer 505 may be formed of the same dielectric material or different dielectric materials.

In addition, in some embodiments, the dielectric portion 507B and the second lower dielectric film 503B collectively form a second lower dielectric portion LD2 over the second gate stack GS2. Accordingly, the second lower dielectric portion LD2 over the second gate stack GS2 in the second region 50B is thicker than the first lower dielectric film LD1 over the first gate stack GS1 in the first region 50A.

Next, referring to FIG. 8 and FIG. 14, method 1400 further includes a block 1404 where a second hydrogen blocking layer 618B is formed on the dielectric film 507 over the second gate stack GS2. In some embodiments, a hydrogen blocking material layer 618 that includes the first portion 618A in the first region 50A and the second portion 618B in the second region 50B may be conformally deposited on the dielectric film 507, using any suitable deposition method.

The hydrogen blocking material layer 618 may include a high-k dielectric material such as aluminum oxide (Al₂O₃), hafnium oxide (HfO₂), zirconium oxide (ZrO₂), or tantalum oxide (Ta₂O₅). In some embodiments, the hydrogen blocking material layer 618 includes aluminum oxide. For example, the hydrogen blocking material layer 618 can be an aluminum oxide layer. In some embodiments, the hydrogen blocking material layer 618 is a composite layer having multiple high-k dielectric sublayers or one high-k dielectric sublayer with one or more sublayers of other materials. The hydrogen blocking material layer 618 and the first hydrogen blocking layer 616A (FIG. 5) may be formed of the same hydrogen blocking material or different hydrogen blocking materials.

In some embodiments, after the foregoing conformal deposition process, the second portion 618B of the hydrogen blocking material layer 618 is deposited on the second lower dielectric portion LD2 over the second gate stack GS2. Since the second portion 618B of the hydrogen blocking material layer 618 will be fabricated into the second hydrogen blocking layer, the second portion 618B can be referred to herein as the second hydrogen blocking layer 618B after the foregoing removal process.

Next, a dielectric refill is performed to cover the structure of FIG. 8.

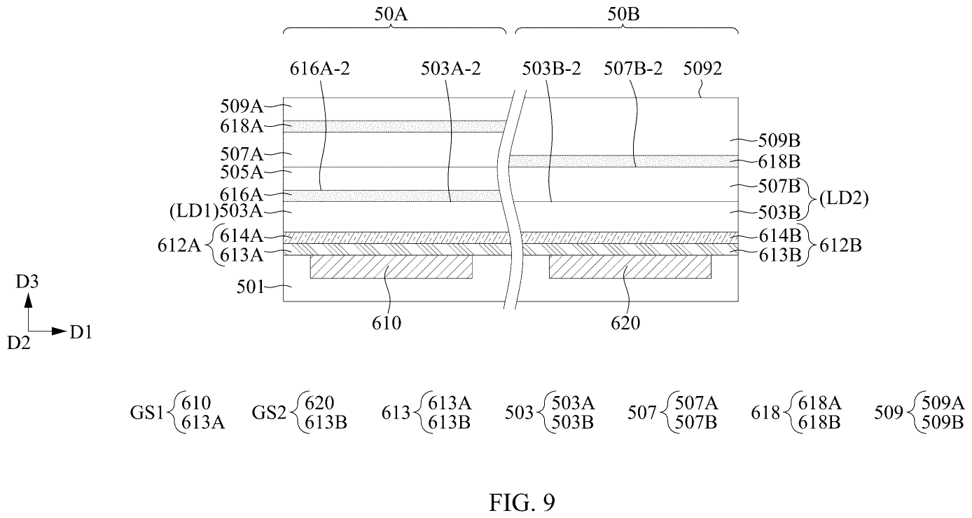

Referring to FIG. 9, in some embodiments, a dielectric material is formed on the hydrogen blocking material layer 618, and then planarized (such as by CMP or any suitable process) to provide a dielectric film 509 with a flat top surface 5092. The dielectric material may include silicon oxide or any suitable insulating material, such as undoped silicate glass, a doped silicate glass, organosilicate glass, or a stack thereof. The dielectric film 509 and the dielectric film 507 may be formed of the same dielectric material or different dielectric materials.

In some embodiments, the dielectric film 509 includes portions 509A and 509B on the first portion 618A and the second portion 618B of the hydrogen blocking material layer 618, respectively. As shown in FIG. 9, in some embodiments, the portion 509B is thicker than the portion 509A. The top surfaces of the portions 509A and 509B are leveled to each other, and collectively form the flat top surface 5092 of the dielectric film 509.

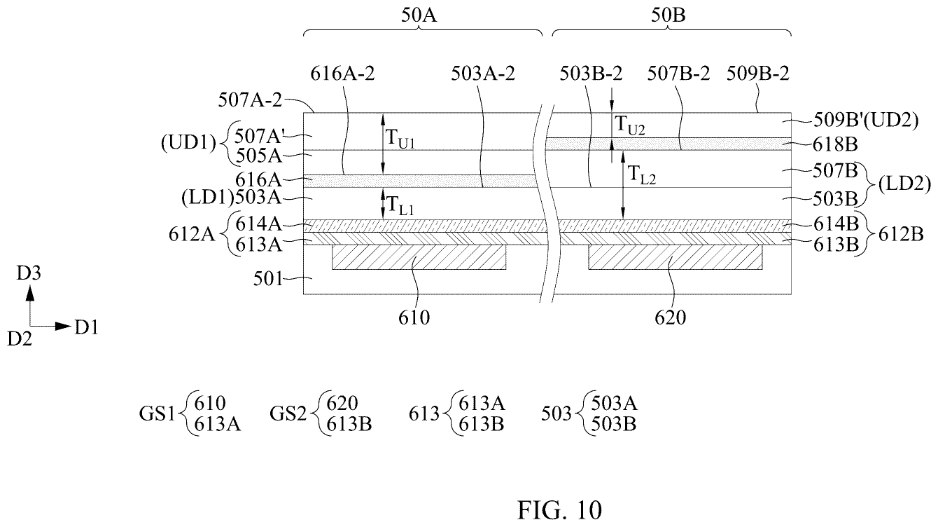

Next, referring to FIG. 10 and FIG. 14, method 1400 includes a block 1405 where a second upper dielectric film UD2 is formed on the second hydrogen blocking layer 618B. In some embodiments, a portion of the dielectric film 509 and the first portion 618A of the hydrogen blocking material layer 618 are removed, using a suitable method, so as to form a first upper dielectric film UD1 on the first hydrogen blocking layer 616A and a second upper dielectric film UD2 on the second hydrogen blocking layer 618B.

In some embodiments, a planarization process, such as a CMP process or the like, may be performed to remove excessive portions of the dielectric film 509 (such as the portion 509A and a part of the portion 509B of the dielectric film 509) and the first hydrogen blocking layer 616A. After the planarization process is performed, the remaining dielectric portion 507A′ and the underlying first dielectric portion 505A collectively form a first upper dielectric film UD1 on the first hydrogen blocking layer 616A. The remaining portion 509B′ of the dielectric film 509 may be referred to as the second upper dielectric film UD2 on the second hydrogen blocking layer 618B.

In some embodiments, the aforementioned planarization process (e.g., CMP) is performed until the first portion 618A of the hydrogen blocking material layer 618 is removed and predetermined thicknesses of the second upper dielectric film UD2 and the first upper dielectric film UD1 are obtained. As shown in FIG. 10, in some embodiments, after the planarization process is performed, the top surface 509B-2 of the second upper dielectric film UD2 on the second hydrogen blocking layer 618B is level with the top surface 507A-2 of the first upper dielectric film UD1 on the first hydrogen blocking layer 616A. In addition, the thickness T_{U1} of the first upper dielectric film UD1 is greater than the thickness T_{U2} of the second upper dielectric film UD2. The thickness T_{L1} of the first lower dielectric film LD1 is less than the thickness T_{L2} of the second lower dielectric portion LD2. In some embodiments, the thickness T_{L1} is about 50 angstroms, and the thickness T_{L2} is about 100 angstroms. However, those numerical values are provided for exemplification purposes only and are not intended to be limiting.

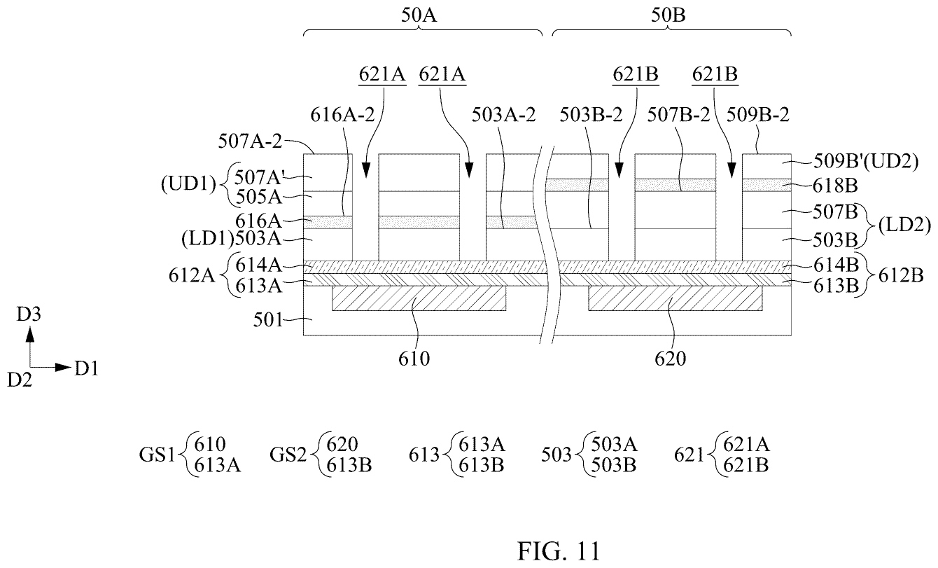

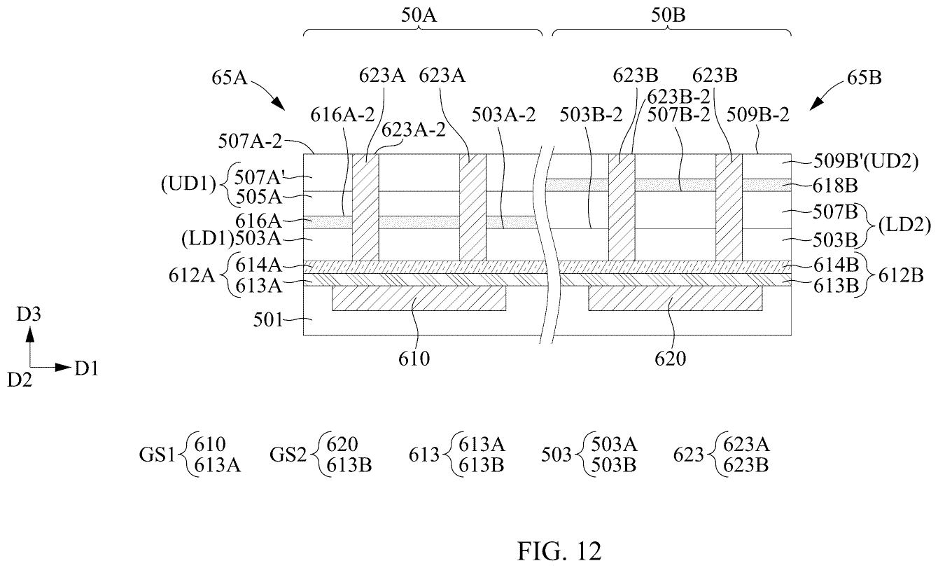

Next, referring to FIG. 11, FIG. 12, and FIG. 14, method 1400 includes a block 1406 where source/drain features 623 are formed over each of the first gate stack GS1 and the second gate stack GS2. The source/drain features 623 are in contact with the channel layer 614. A source/drain feature 623 may refer to a source or a drain, individually or collectively, dependent upon the context.

In some embodiments, as shown in FIG. 11, first trenches 621A are formed over the first gate stack GS1, and second trenches 621B are formed over the second gate stack GS2. The first trenches 621A expose the first channel layer 614A. The second trenches 621B expose the second channel layer 614B.

A photoresist layer (not shown) may be formed on the first upper dielectric film UD1 and the second upper dielectric film UD2. The photoresist layer may be lithographically patterned to form a pattern that corresponds to trenches for forming source/drain features. Using a suitable method, the pattern of the photoresist layer may be transferred to the material layers over the first channel layer 614A and the second channel layer 614B. For example, using the patterned photoresist layer (not shown) as a mask, the material layers over the channel layer 614 may be etched by one or more suitable etching processes.

Next, in some embodiments, source/drain features 623 are formed in the trenches 621. As shown in FIG. 12, the source/drain features 623A are formed in the first trenches 621A and in contact with the first channel layer 614A. The source/drain features 623B are formed in the second trenches 621B and in contact with the second channel layer 614B.

The formation of the source/drain features 623 may include operations below. For example, an electrically conductive material may be deposited on the first upper dielectric film UD1 and the second upper dielectric film UD2, fully filling the trenches 621. Then, a planarization process, such as a chemical mechanical polishing (CMP) process or the like, may then be performed to remove excess amounts of the electrically conductive material over the top surfaces of the first upper dielectric film UD1 and the second upper dielectric film UD2, thereby forming the source/drain features 623A in the first trenches 621A and the source/drain features 623B in the second trenches 621B.

After planarization, the top surfaces 623A-2 of the source/drain features 623A are coplanar with the top surface 507A-2 of the first upper dielectric film UD1; and the top surfaces 623B-2 of the source/drain features 623B are coplanar with the top surface 509B-2 of the second upper dielectric film UD2. The source/drain features 623A and 623B may extend parallel to one another (e.g., along the direction D2), and may be spaced apart according to a desired pitch.

Specifically, in this exemplary embodiment, each of the source/drain features 623A in the first region 50A penetrates the first upper dielectric film UD1 (including the remaining extending dielectric portion 507A′ and the first dielectric portion 505A), the first hydrogen blocking layer 616A, and the first lower dielectric film LD1 (i.e., dielectric film 503A). In this exemplary embodiment, each of the source/drain features 623B in the second region 50B penetrates the second upper dielectric film UD2 (i.e., the remaining portion 509B′ of the dielectric film 509 in FIG. 10), the second hydrogen blocking layer 618B, and the second lower dielectric portion LD2 (including the dielectric portion 507B and the second lower dielectric film 503B).

According to the embodiments of the present disclosure, the source/drain features 623A and 623B have the same height; however, the second lower dielectric portion LD2 and the first lower dielectric film have different thicknesses. For example, as shown in FIG. 12, the second hydrogen blocking layer 618B in the second region 50B is formed above the level of the first hydrogen blocking layer 616A in the first region 50A. Therefore, the second lower dielectric portion LD2 between the second channel layer 614B and the second hydrogen blocking layer 618B is thicker than the first lower dielectric film LD1 between the first channel layer 614A and the first hydrogen blocking layer 616A.

In some embodiments, a first TFT 65A in the first region 50A includes the first gate stack GS1 (e.g., including the first gate electrode 610 and the first gate dielectric layer 613A), the first channel layer 614A, the first hydrogen blocking layer 616A, and the source/drain features 623A in contact with the first channel layer 614A. The first hydrogen blocking layer 616A in the first region 50A is formed to prevent outgassing of hydrogen in the first lower dielectric film LD1.

In some embodiments, a second TFT 65B in the second region 50B includes the second gate stack GS2 (e.g., including the second gate electrode 620 and the second gate dielectric layer 613B), the second channel layer 614B, and the source/drain features 623B in contact with the second channel layer 614B. The second hydrogen blocking layer 618B in the second region 50B is formed to prevent outgassing of hydrogen in the second lower dielectric portion LD2. Since the thicknesses of the first lower dielectric film LD1 and the second lower dielectric portion LD2 are different, the hydrogen concentrations of the first lower dielectric film LD1 and the second lower dielectric portion LD2 are different.

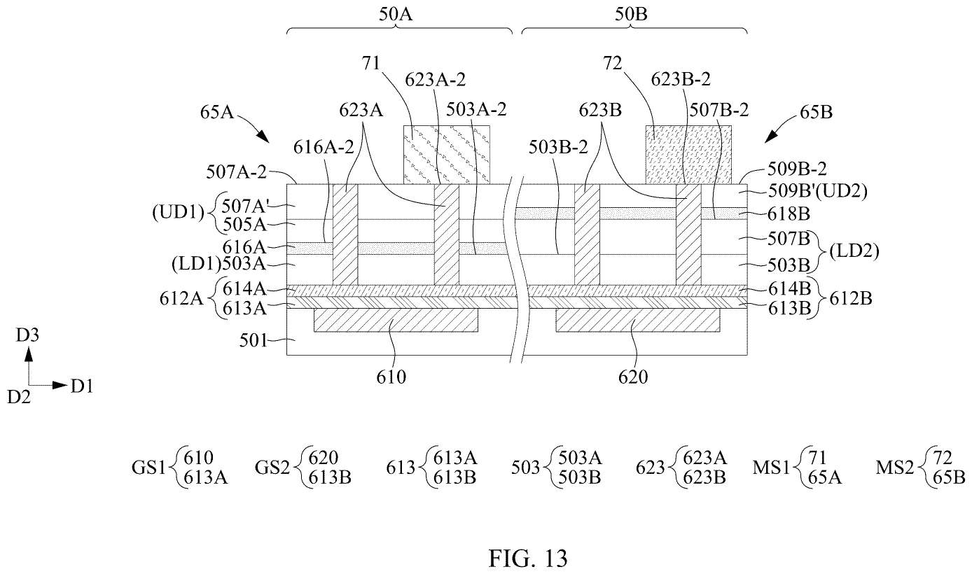

Referring to FIG. 13 and FIG. 14, method 1400 includes a block 1407, wherein a memory cell is formed on one of the source/drain features 623 over each of the first gate stack GS1 and the second gate stack GS2. Each of the memory structures may include a transistor (such as a TFT) and a memory cell on the transistor. The transistor may act as a selector for the memory cell formed thereon.

In some embodiments, as shown in the first region 50A of FIG. 13, a first memory cell 71 is formed on one of the source/drain features 623A (such as on a drain), and the first TFT 65A acts as a selector for the first memory cell 71. A first memory structure MS1 includes the first TFT 65A and the first memory cell 71 formed on and coupled to the first TFT 65A. The first TFT 65A may be configured to selectively supply power to the first memory cell 71.

In some embodiments, as shown in the second region 50B of FIG. 13, a second memory cell 72 is formed on one of the source/drain features 623B (such as on a drain), and the second TFT 65B acts as a selector for the second memory cell 72. A second memory structure MS2 includes the second TFT 65B and the second memory cell 72 formed on and coupled to the second TFT 65B. The second TFT 65B may be configured to selectively supply power to the second memory cell 72.

In some embodiments where the channel layer 614 includes a semiconducting oxide material (such as IGZO, or another suitable material), the TFT performance shows high sensitivity to the hydrogen concentration. In some embodiments, the second lower dielectric portion LD2 is thicker than the first lower dielectric film LD1. Consequently, the hydrogen concentration of the second lower dielectric portion LD2 of the second TFT is greater than the hydrogen concentration of the first lower dielectric film LD1 of the first TFT. Therefore, the threshold voltage (Vt) of the first TFT 65A is higher than the threshold voltage (Vt) of the second TFT 65B. The first TFT 65A may be referred to as a high-Vt device or a high-Vt selector. The second TFT 65B may be referred to as a low-Vt device or a low-Vt selector.

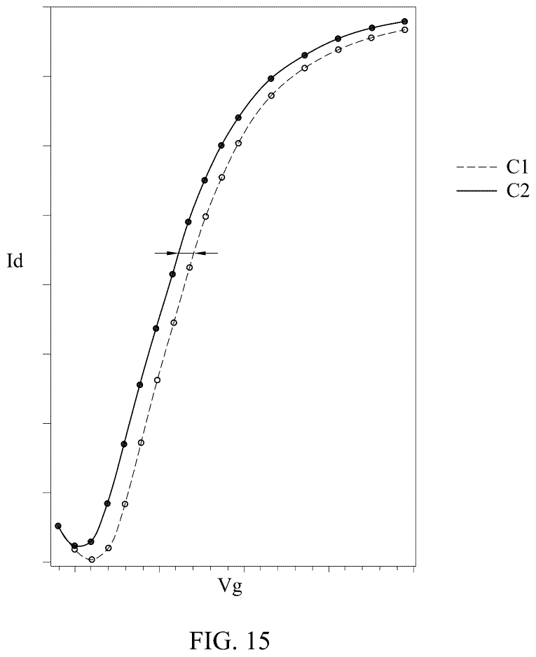

FIG. 15 is a graph showing the results of evaluating gate voltage-drain current (Vg-Id) characteristics of a low-Vt device and a high-Vt device. Curve C1 represents a Vg-Id characteristic of a low-Vt device. Curve C2 represents a Vg-Id characteristic of a high-Vt device. The high-Vt device (or high-Vt selector) has advantages of low leakage current. In some applications, the high-Vt device (or high-Vt selector), such as the first TFT 65A described above, can be used as a well control selector for reducing the memory standby power of the first memory cell 71. The low-Vt device (or low-Vt selector) has advantages of high on-current. In some applications, the low-Vt device (or low-Vt selector), such as the second TFT 65B described above, eliminates delay time with high on-current, and is suitable for combining with a high bandwidth memory (HBM) or similar memory cell to enhance memory switching speed.

According to the embodiments of the present disclosure, several devices (such as transistors) with different threshold voltages can be simultaneously fabricated on the same wafer by the method provided above. The threshold voltage varies with the thickness of the dielectric layer (e.g., the first lower dielectric film LD1 or the second lower dielectric portion LD2) between the channel layer (e.g., 614A, 614B) and the hydrogen blocking layer (e.g., 616A, 618B). According to the method of some embodiments, one extra mask (e.g., the patterned photoresist layer 506) is added during the thickness definition of the dielectric layer. In addition, those devices with different threshold voltages may be transistors that act as selectors for the memory cells formed thereon. In some applications, several memory cells with different types can be selected by suitable devices with different threshold voltages. For example, the first memory cell 71 may be a memory cell that is selected by a high-Vt device (e.g., the first TFT 65A) with low leakage behavior for reducing power consumption. The second memory cell 72 may be a HBM cell that is selected by a low-Vt device (e.g., the second TFT 65B) for enhancing memory switching speed. Thus, according to the embodiments, the thickness variation of the dielectric layer (e.g., LD1, LD2) can make Vt controllable, so as to enhance selector application. In addition, the fabricated high-Vt and low-Vt devices (or selectors) are compatible with any FEOL and BEOL processes.

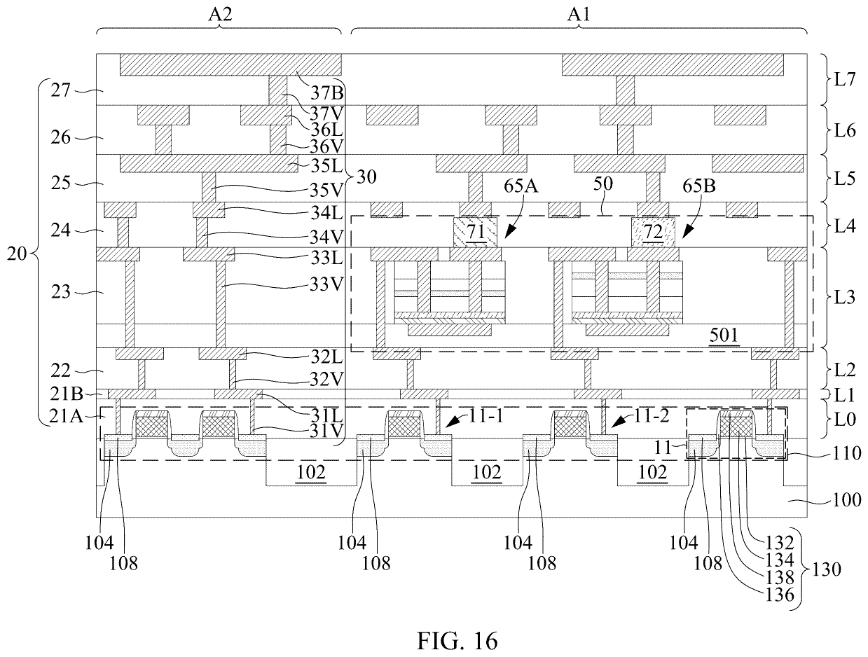

FIG. 16 is a cross-sectional view of an exemplary semiconductor structure with upper-level metal interconnect structures, including an array 50 of memory structures, in accordance with some embodiments of the present disclosure. The memory structures MS1 and MS2, as shown in FIG. 13, are formed within the semiconductor structure. In some embodiments, the transistors of the memory structures, such as the first TFT 65A and the second TFT 65B of the memory structures MS1 and MS2, are formed at the third level of the semiconductor structure and are parts of the third interconnect-level structure L3. The memory cells on the TFTs, such as the first memory cell 71 and the second memory cell 72, may be formed at the fourth level and may be parts of a fourth interconnect-level structure L4. As shown in FIG. 16, the first memory cell 71 and the second memory cell 72 are formed within the dielectric layer 24 of the fourth interconnect-level structure L4.

In some embodiments, the CMOS circuitry 110 includes a first field effect transistor (FET) 11-1 and a second FET 11-2. After forming a FEOL structure, such as structures (e.g., FETs) on the substrate 100 and the lower interconnect-level structures (L0, L1, L2), the third level of the semiconductor structure that includes the first TFT 65A and the second TFT 65B is formed on the FEOL structure. The first TFT 65A is coupled to the first FET 11-1, and the second TFT 65B is coupled to the second FET 11-2.

Specifically, in some embodiments, one of the source/drain features 623 of the first TFT 65A is coupled to the first FET 11-1 by the third interconnect-level metal interconnect structures (33V, 33L), the second interconnect-level metal interconnect structures (32V, 32L), the first metal lines 31L, and the contact via structure 31V, as shown in FIG. 16. The first FET 11-1 may supply power to the first TFT 65A. Similarly, one of the source/drain features 623 of the second TFT 65B is coupled to the second FET 11-2 by the third interconnect-level metal interconnect structures (33V, 33L), the second interconnect-level metal interconnect structures (32V, 32L), the first metal lines 31L, and the contact via structure 31V. The second FET 11-2 may supply power to the second TFT 65B. In some embodiments, the first TFT 65A is electrically independent from the second TFT 65B.

According to the manufacturing method of the embodiments, the threshold voltage of the transistor of each of the memory structures on one wafer is tunable by altering the thickness of the dielectric layer between the channel layer and the hydrogen blocking layer of the transistor without performing any doping process.

In some exemplary embodiments, as shown in FIG. 12, of the first TFT 65A and the second TFT 65B, the first hydrogen blocking layer 616A is formed on the top surface of the first lower dielectric film LD1 and extends over the first channel layer 614A. The second hydrogen blocking layer 618B is formed on the top surface of the second lower dielectric portion LD2 and extends over the second channel layer 614B. In some other exemplary embodiments, the hydrogen blocking layer may be formed on the lower dielectric portion/film, covering the top surface and lateral surfaces of the lower dielectric portion/film, as well as the lateral surfaces o f the channel layer. One of the applicable methods is described below.

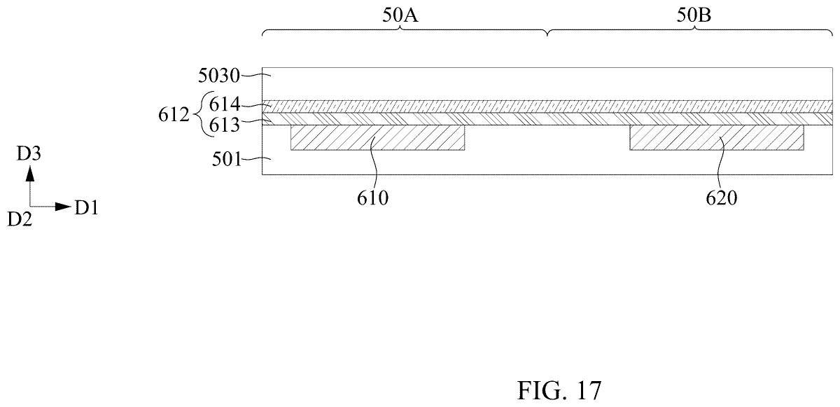

FIGS. 17 to 28 are fragmentary cross-sectional views illustrating a method of forming memory structures at various intermediate stages, in accordance with some embodiments of the present disclosure. The features/components in FIGS. 17 to 28 that are similar or identical to the features/components in FIGS. 4 to 13 are designated with similar or the same reference numbers. Details of the arrangement, materials, and manufacturing methods of those similar or identical features/components shown in FIGS. 17 to 28 are essentially the same as those discussed with reference to FIGS. 4 to 13, and are not repeated herein.

Referring to FIG. 17, in some embodiments, a first gate electrode 610 is formed in the insulating material layer 501 within the first region 50A, and a second gate electrode 620 is formed in the insulating material layer 501 within the second region 50B. A gate dielectric layer 613, a channel layer 614, and a dielectric material 5030 are sequentially formed over the insulating material layer 501. The gate dielectric layer 613, the channel layer 614, and the dielectric material 5030 continuously extend over the first gate electrode 610 and the second gate electrode 620.

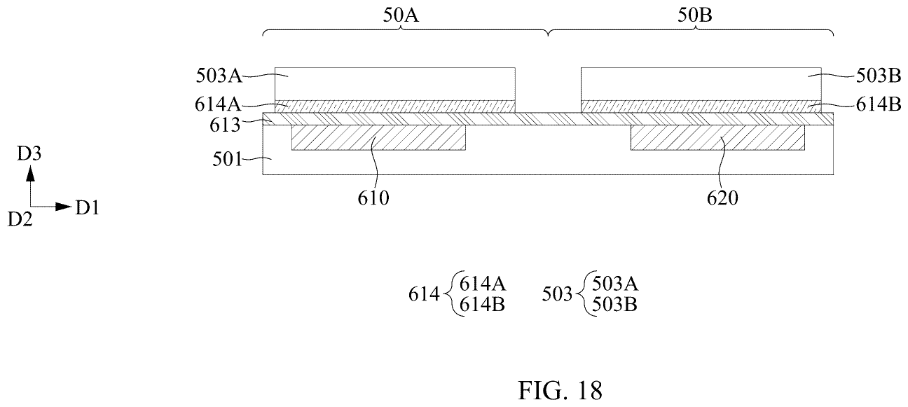

Referring to FIG. 18, in some embodiments, the dielectric material 5030 and the channel layer 614 are patterned, using a suitable lithography method, to form the first lower dielectric film 503A and the first channel layer 614A in the first region 50A, and the second lower dielectric film 503B and the second channel layer 614B in the second region 50B. The second lower dielectric film 503B is separated from the first lower dielectric film 503A. The second channel layer 614B is separated from the first channel layer 614A.

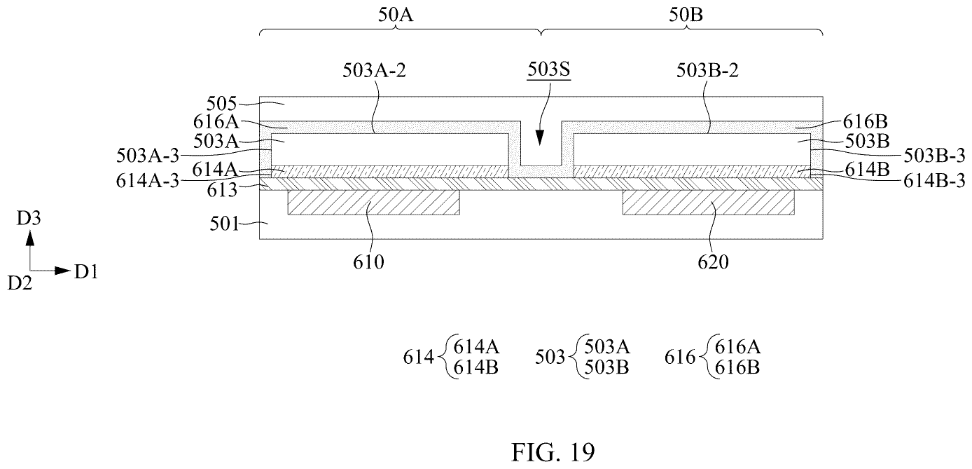

Referring to FIG. 19, in some embodiments, a hydrogen blocking material layer 616 is conformally deposited on the first lower dielectric film 503A and the second lower dielectric film 503B, and deposited as a liner in the spacing 503S between the first lower dielectric film 503A and the second lower dielectric film 503B. The hydrogen blocking material layer 616 includes a first portion 616A in the first region 50A and a second portion 616B in the second region 50B.

Specifically, in this exemplary embodiment, the first portion 616A covers the top surface 503A-2 and the lateral surfaces 503A-3 of the first lower dielectric film 503A, and also covers the lateral surfaces 614A-3 of the first channel layer 614A. The second portion 616B covers the top surface 503B-2 and the lateral surfaces 503B-3 of the second lower dielectric film 503B, and also covers the lateral surfaces 614B-3 of the second channel layer 614B.

Next, in some embodiments, a second dielectric layer 505 is formed on the hydrogen blocking material layer 616, using any suitable deposition method. Optionally, the second dielectric layer 505 may be planarized to provide a flat top surface, as shown in FIG. 19.

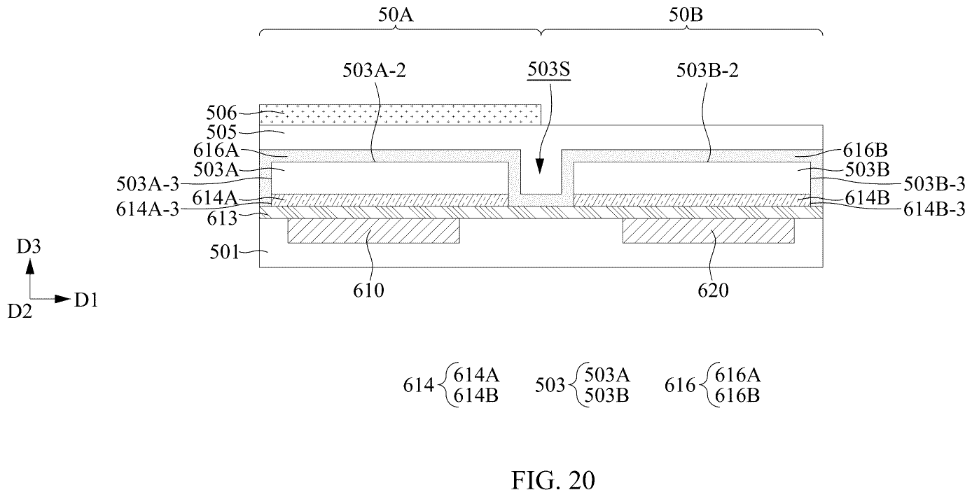

Referring to FIG. 20, in some embodiments, a patterned photoresist layer 506 is formed on the second dielectric layer 505. The patterned photoresist layer 506 shields the layers in the first region 50A and exposes the layers in the second region 50B. For example, the patterned photoresist layer 506 shields a portion of the second dielectric layer 505, the first portion 616A of the hydrogen blocking material layer 616, the first lower dielectric film 503A, the first channel layer 614A, and the first gate electrode 610 in the first region 50A.

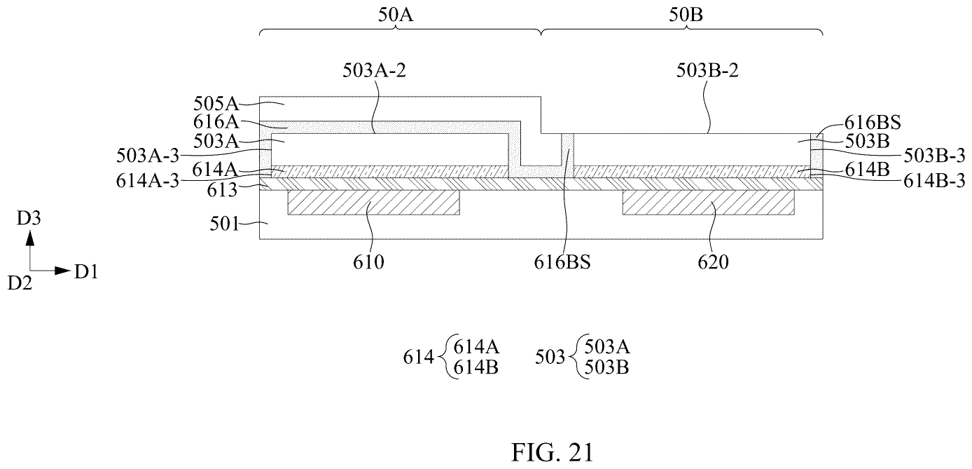

Referring to FIG. 21, in some embodiments, a portion of the layers in the second region 50B that is uncovered by the patterned photoresist layer 506 is removed using any suitable process (e.g., by one or more etching processes). For example, a portion of the second dielectric layer 505 in the second region 50B and parts of the second portion 616B of the hydrogen blocking material layer 616 are removed. As shown in FIG. 21, the second lower dielectric film 503B is exposed. In some embodiments, the remaining part 616BS of the second portion 616B of the hydrogen blocking material layer 616 covers the lateral surfaces 503B-3 of the second lower dielectric film 503B and the lateral surfaces 614B-3 of the second channel layer 614B. In addition, the remaining portion of the second dielectric layer 505 includes the first dielectric portion 505A in the first region 50A.

Next, add more dielectric on the second lower dielectric film 503B to form a thicker dielectric portion (i.e., the second lower dielectric portion LD2) over the second gate electrode 620, in accordance with some embodiments of the present disclosure.

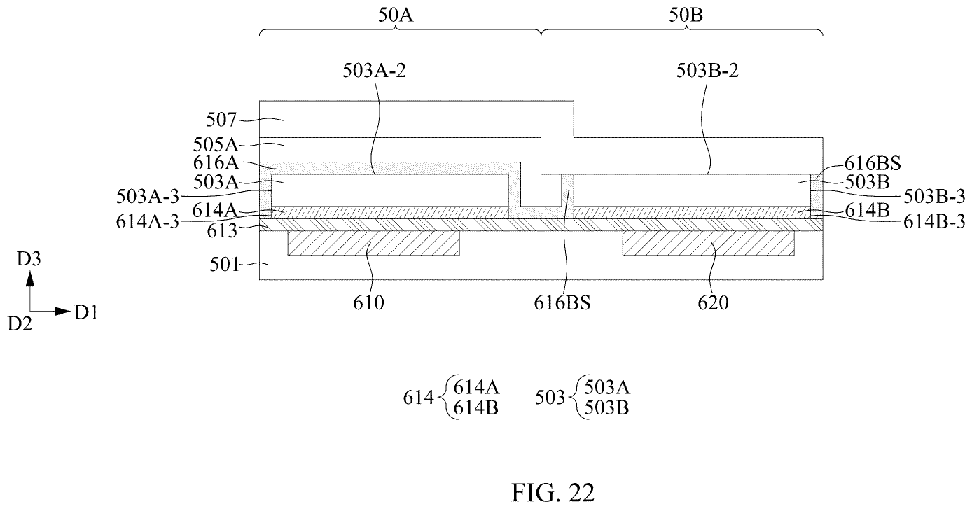

Referring to FIG. 22, in some embodiments, a dielectric film 507 is conformally deposited on the structure in FIG. 21. The dielectric film 507 includes a dielectric portion 507A on the first dielectric portion 505A.

Optionally, in some embodiments, an additional removing step may be operated to form a second lower dielectric portion LD2 fully covered by a second hydrogen blocking layer 616B subsequently.

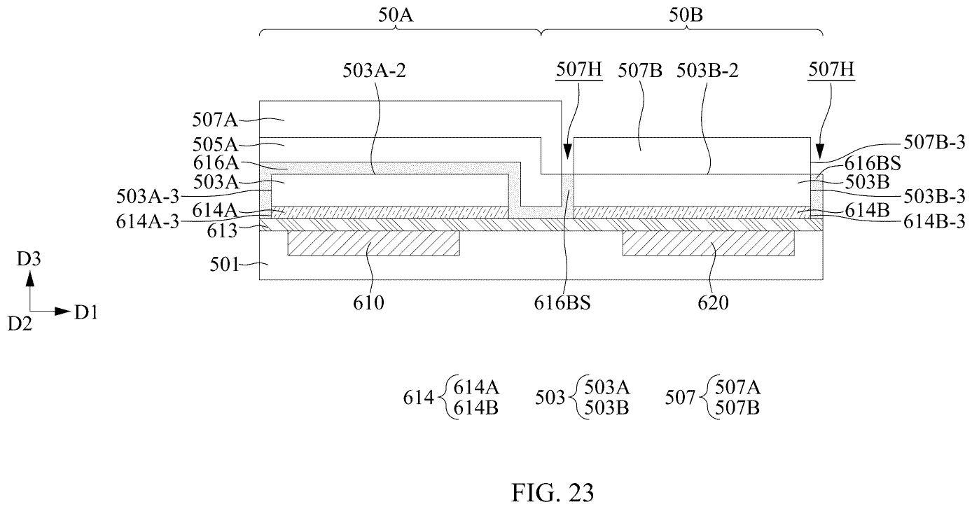

Referring to FIG. 23, in some embodiments, a portion of the dielectric film 507 is optionally removed to form a cavity 507H, and a dielectric portion 507B remains on the second lower dielectric film 503B. The cavity 507H exposes the remaining part 616BS of the second portion 616B of the hydrogen blocking material layer 616 in the second region 50B. In addition, the cavity 507H exposes lateral surfaces 507B-3 of the dielectric portion 507B. In some embodiments, the lateral surfaces 507B-3 of the dielectric portion 507B are substantially aligned with the lateral surfaces 503B-3 of the second lower dielectric film 503B. The width (e.g., in the direction D1) of the cavity 507H may be substantially equal to or greater than the width of the remaining parts 616BS of the second portion 616B of the hydrogen blocking material layer 616.

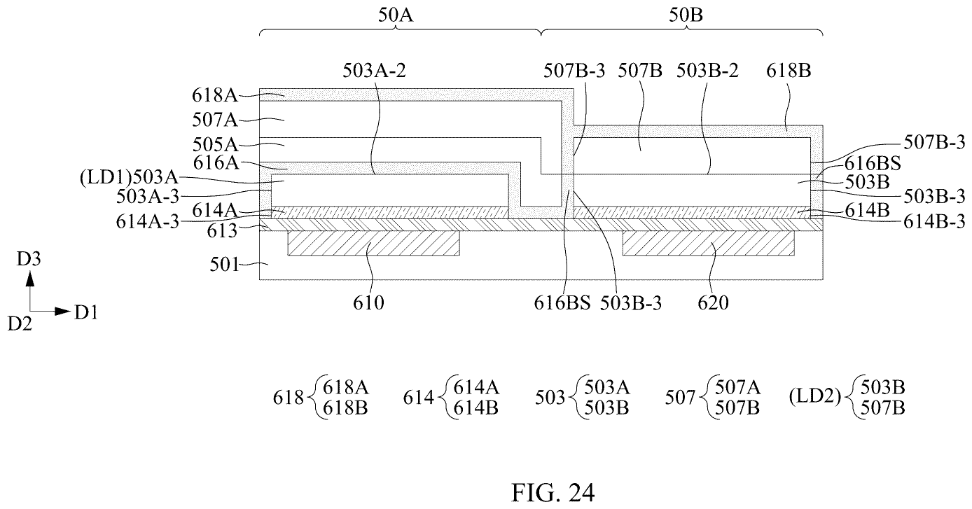

Referring to FIG. 24, in some embodiments, a hydrogen blocking material layer 618, which includes the first portion 618A in the first region 50A and the second portion 618B in the second region 50B, is conformally deposited on the dielectric film 507, using any suitable deposition method. The hydrogen blocking material layer 618 also fills the cavity 507H. The hydrogen blocking material layer 618 and the hydrogen blocking material layer 616 (FIG. 19) may be formed of the same hydrogen blocking material or different hydrogen blocking materials.

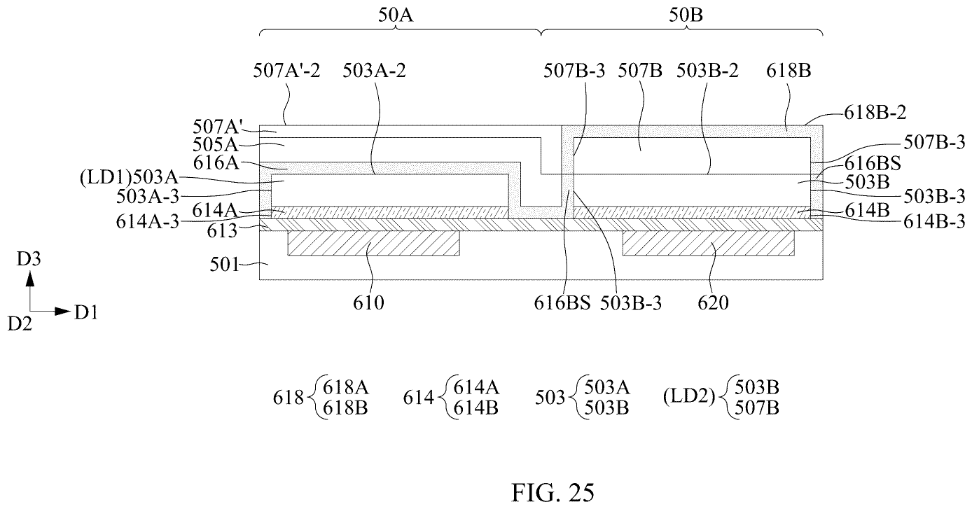

Referring to FIG. 25, in some embodiments, the first portion 618A of the hydrogen blocking material layer 618 and a part of the dielectric portion 507A that is above the horizontal level of the second portion 618B of the hydrogen blocking material layer 618 are removed, for example, using a planarization process, such as a CMP process. After the removal step, the top surface 507A′-2 of the remaining dielectric portion 507A′ may be substantially coplanar with the top surface 618B-2 of the second portion 618B.

According to some embodiments, the first portion 616A of the hydrogen blocking material layer 616 can be referred to as a first hydrogen blocking layer 616A in the first region 50A, and the second portion 618B of the hydrogen blocking material layer 618 can be referred to as a second hydrogen blocking layer 616B in the second region 50B.

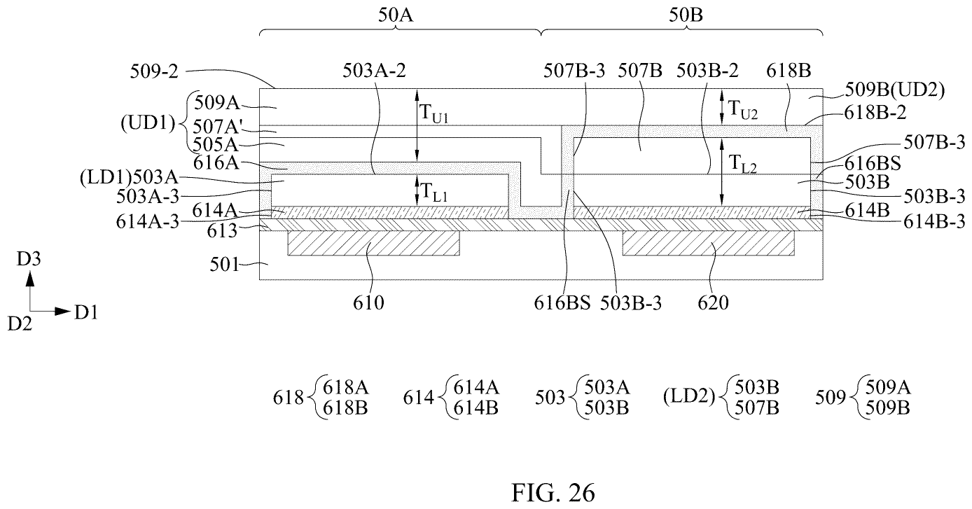

Referring to FIG. 26, in some embodiments, a dielectric material is formed on the second hydrogen blocking layer 618B and the remaining dielectric portion 507A′. Then, the dielectric material is planarized (such as by CMP or any suitable process) to provide a dielectric film 509 with a flat top surface 5092. The dielectric film 509 and the dielectric film 507 may include the same dielectric material or different dielectric materials.

In some embodiments, the dielectric film 509 includes portions 509A and 509B on the remaining dielectric portion 507A′ and the second hydrogen blocking layer 618B, respectively. As shown in FIG. 26, the portion 509A of the dielectric film 509, the remaining dielectric portion 507A′, and the first dielectric portion 505A in the first region 50A collectively form a first upper dielectric film UD1 on the first hydrogen blocking layer 616A. The portion 509B of the dielectric film 509 on the second hydrogen blocking layer 618B can be referred to as a second upper dielectric film UD2 in the second region 50B. The thickness T_{U1} of the first upper dielectric film UD1 is greater than the thickness T_{U2} of the second upper dielectric film UD2.

In some embodiments, the first lower dielectric film 503A can be referred to as a first lower dielectric film LD1 in the first region 50A. The dielectric portion 507B and the second lower dielectric film 503B collectively form a second lower dielectric portion LD2 in the second region 50B. The thickness T_{L2} of the second lower dielectric portion LD2 is greater than the thickness T_{L1} of the first lower dielectric film LD1.

In addition, in this exemplary embodiment, the first hydrogen blocking layer 616A covers the top surface and the lateral surfaces of the first lower dielectric film LD1, thereby preventing outgassing of hydrogen in the first lower dielectric film LD1. Similarly, the second hydrogen blocking layer 618B covers the top surface and the lateral surfaces of the second lower dielectric portion LD2, thereby preventing outgassing of hydrogen in the second lower dielectric portion LD2.

Although operations in FIGS. 25 and 26 illustrate that a removal step is performed after depositing the hydrogen blocking material layer 618 (FIG. 25), and a dielectric film 509 with a flat top surface 5092 is formed on the second hydrogen blocking layer 618B (FIG. 26), the disclosure is not limited thereto. In some other embodiments, steps similar to the operations as exemplified in FIGS. 9 and 10 may be performed. That is, after the hydrogen blocking material layer 618 is conformally deposited (FIG. 24), a dielectric film is formed on the hydrogen blocking material layer 618, a portion of the dielectric film and the first portion 618A of the hydrogen blocking material layer 618 are removed, so as to form a first upper dielectric film UD1 on the first hydrogen blocking layer 616A and a second upper dielectric film UD2 on the second hydrogen blocking layer 618B.

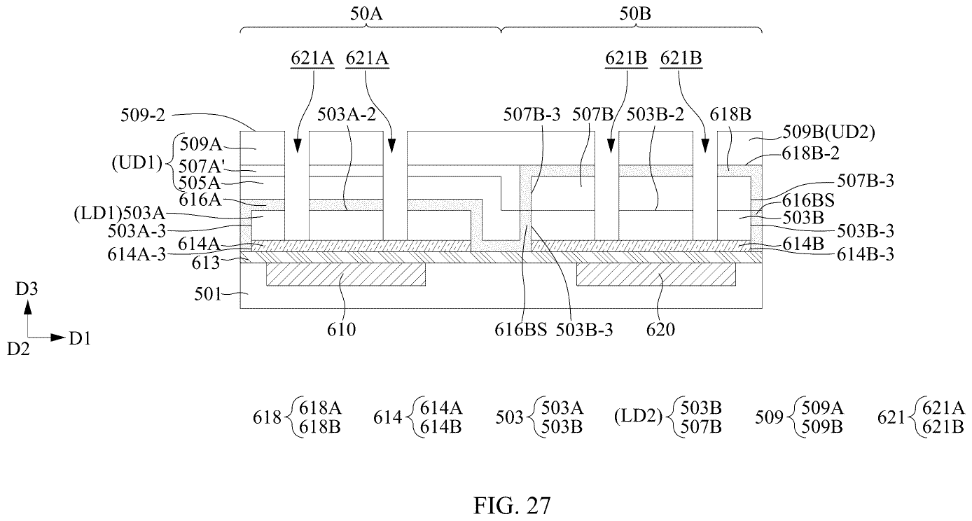

Referring to FIG. 27, in some embodiments, first trenches 621A are formed to penetrate the first upper dielectric film UD1, the first hydrogen blocking layer 616A, and the first lower dielectric film LD1. The bottoms of the first trenches 621A expose the first channel layer 614A. Similarly, second trenches 621B are formed to penetrate the second upper dielectric film UD2, the second hydrogen blocking layer 618B, and the second lower dielectric portion LD2. The bottoms of the second trenches 621B expose the second channel layer 614B.

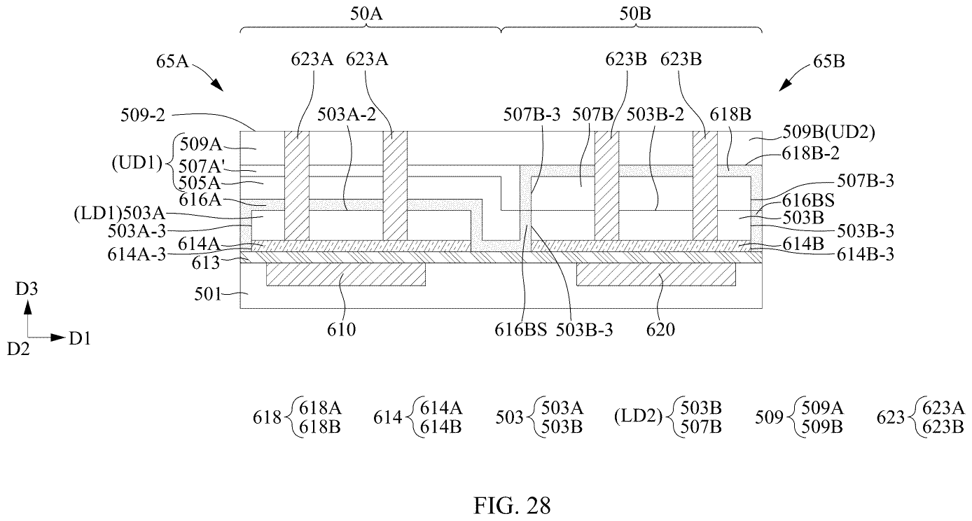

Referring to FIG. 28, in some embodiments, source/drain features 623 are formed in the trenches 621. As shown in FIG. 28, the source/drain features 623A are formed in the first trenches 621A and in contact with the first channel layer 614A. The source/drain features 623B are formed in the second trenches 621B and in contact with the second channel layer 614B. The source/drain features 623A and 623B may be referred to as source/drain features 623.

Accordingly, a first TFT 65A and a second TFT 65B are formed in the first region 50A and the second region 50B, respectively. In some embodiments, the first TFT 65A includes the first gate electrode 610, the gate dielectric layer 613, the first channel layer 614A, the first hydrogen blocking layer 616A, and the source/drain features 623A. The source/drain features 623A are in contact with the first channel layer 614A. The first hydrogen blocking layer 616A in the first region 50A is formed to prevent the outgassing of hydrogen in the first lower dielectric film LD1. In some embodiments, the second TFT 65B includes the second gate electrode 620, the gate dielectric layer 613, the second channel layer 614B, the second hydrogen blocking layer 616B, and the source/drain features 623B. The source/drain features 623B are in contact with the second channel layer 614B. The second hydrogen blocking layer 616B in the second region 50B is formed to prevent the outgassing of hydrogen in the second lower dielectric film LD2.

Next, a memory cell is formed on and coupled to each of the first TFT 65A and the second TFT 65B. For example, a first memory cell 71 is formed on one of the source/drain features 623A, and a second memory cell 72 is formed on one of the source/drain features 623B, as illustrated in FIG. 13. The first TFT 65A is configured to selectively supply power to t he first memory cell 71, and the second TFT 65B is configured to selectively supply power to the second memory cell 72. As described above, threshold voltage (Vt) of the first TFT 65A is higher than threshold voltage (Vt) of the second TFT 65B since the second lower dielectric portion LD2 is thicker than the first lower dielectric film LD1. Accordingly, the first TFT 65A can be referred to as a high-Vt device, and the second TFT 65B can be referred to as a low-Vt device. That is, the first TFT 65A acts as a high-Vt selector for the first memory cell 71, and the second TFT 65B acts as a low-Vt selector for the second memory cell 72.

Although not intended to be limiting, one or more embodiments of the present disclosure provide many benefits to a semiconductor structure having memory structures and methods of forming the memory structures. According to the aforementioned description, several memory structures are formed in BEOL of a semiconductor structure. In some embodiments, each of the memory structures includes a transistor (such as a TFT) and a memory cell formed on and coupled to the transistor (e.g., TFT). Transistors with different threshold voltages can be simultaneously fabricated on a wafer, using the methods provided in some embodiments. Those transistors with different threshold voltages may act as selectors for the memory cells formed thereon. In some embodiments, the threshold voltage of each of the transistors can be controlled by varying the thickness of a dielectric layer between the hydrogen blocking layer and the channel layer, while uppermost surfaces of the transistors are coplanar and form a flat top surface on which the memory cells are formed. In some applications, several memory cells with different types can be selected by suitable transistors with different threshold voltages, which enhances selector application. For example, one or more memory cells can be selected by high-Vt transistors with low leakage behavior for reducing power consumption, and one or more memory cells (such as HBM) can be selected by low-Vt transistors for enhancing memory switching speed. Those high-Vt transistors, low-Vt transistors, and memory cells can be formed on the same wafer. In addition, fabrication of the high-Vt and low-Vt transistors are compatible with FEOL and BEOL processes.

In one exemplary aspect, the present disclosure is directed to a method of forming a semiconductor structure. The method includes forming a memory structure over a substrate, which includes forming a first gate stack and a second gate stack over a substrate, and forming a channel layer on the first gate stack and the second gate stack. The method of forming the memory structure further includes providing a first lower dielectric film over the first gate stack, a first hydrogen blocking layer on the first lower dielectric film, and a second lower dielectric film over the second gate stack, wherein no hydrogen blocking layer is formed on the second lower dielectric film. The method of forming the memory structure further includes forming a dielectric film on the second lower dielectric film, thereby collectively forming a second lower dielectric portion that is thicker than the first lower dielectric film. The method of forming the memory structure further includes forming a second hydrogen blocking layer on the dielectric film over the second gate stack, and forming a second upper dielectric film on the second hydrogen blocking layer. The method of forming the memory structure further includes forming source/drain features over each of the first gate stack and the second gate stack, and forming a memory cell on one of the source/drain features over each of the first gate stack and the second gate stack. The method further includes forming an interconnect structure over the source/drain features and the memory cell. The interconnect structure includes metal lines disposed in interconnect dielectric layers, and the memory cell is formed in one of the interconnect dielectric layers.

In another exemplary aspect, the present disclosure is directed to a method of forming a semiconductor structure. The method includes forming a transistor having active regions in a substrate, and forming a memory structure over the substrate and above the transistor. The method of forming the memory structure includes forming a first gate electrode and a second gate electrode over the substrate and above the transistor. The method of forming the memory structure further includes forming a first selector layer on the first gate electrode and a second selector layer on the second gate electrode. The method of forming the memory structure further includes forming a patterned dielectric layer on the first selector layer and the second selector layer. The patterned dielectric layer includes a first hydrogen blocking layer on a first lower dielectric film that is on the first selector layer; a dielectric portion on the first hydrogen blocking layer; and a second lower dielectric film on the second selector layer, wherein a top surface of the second lower dielectric film is exposed and lower than a top surface of the first hydrogen blocking layer. The method of forming the memory structure further includes forming a dielectric film on the second lower dielectric film, and forming a second hydrogen blocking layer on the dielectric film over the second selector layer. The method of forming the memory structure further includes forming a second upper dielectric film on the second hydrogen blocking layer, and forming source/drain features on each of the first selector layer and the second selector layer. The transistor is coupled to one of the source/drain features on the first selector layer or the second selector layer. The method of forming the memory structure further includes forming a memory cell on one of the source/drain features on the first selector layer and the second selector layer.

In yet another exemplary aspect, the present disclosure is directed to a semiconductor structure, including a first TFT and a second TFT over a substrate and separated from each other. Each of the first TFT and the second TFT includes a gate stack over the substrate, a channel layer on the gate stack, a dielectric layer on the channel layer, a hydrogen blocking layer buried in the middle of the dielectric layer, source/drain features formed in the dielectric layer and in contact with the channel layer. The hydrogen blocking layers of the first TFT and the second TFT are positioned at different levels. The memory structure further includes an interconnect structure disposed over the first TFT and the second TFT, wherein the interconnect structure includes metal lines disposed in interconnect dielectric layers. The memory structure further includes a first memory cell formed on the first TFT and in one of interconnect dielectric layers. The first memory cell is electrically connected to one of the source/drain features of the first TFT. The memory structure further includes a second memory cell formed on the second TFT and in one of interconnect dielectric layers. The second memory cell is electrically connected to one of the source/drain features of the second TFT.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a memory structure over a substrate, comprising:
forming a first gate stack and a second gate stack over the substrate;
forming a channel layer on the first gate stack and the second gate stack;
providing a first lower dielectric film over the first gate stack, a first hydrogen blocking layer on the first lower dielectric film, and a second lower dielectric film over the second gate stack, wherein no hydrogen blocking layer is formed on the second lower dielectric film;
forming a dielectric film on the second lower dielectric film, thereby collectively forming a second lower dielectric portion that is thicker than the first lower dielectric film;
forming a second hydrogen blocking layer on the dielectric film over the second gate stack;
forming a second upper dielectric film on the second hydrogen blocking layer;
forming source/drain features over each of the first gate stack and the second gate stack; and
forming a memory cell on one of the source/drain features over each of the first gate stack and the second gate stack; and
forming an interconnect structure over the source/drain features and the memory cell, wherein the interconnect structure comprises a plurality of metal lines disposed in the plurality of interconnect dielectric layers, and the memory cell is formed in one of the interconnect dielectric layers.

2. The method of claim 1, wherein a top surface of the second lower dielectric portion is above a level of a top surface of the first hydrogen blocking layer.

3. The method of claim 1, wherein a top surface of the second upper dielectric film on the second hydrogen blocking layer is level with a top surface of a first upper dielectric film on the first hydrogen blocking layer.

4. The method of claim 1, further comprising a transistor formed in a lower interconnect-level structure that is under the first gate stack and the second gate stack, wherein the transistor is coupled to one of the source/drain features over one of the first gate stack and the second gate stack.

5. The method of claim 1, wherein a top surface of the second lower dielectric film is coplanar with a top surface of the first lower dielectric film.

6. The method of claim 1, wherein providing the first lower dielectric film and the second lower dielectric film comprises:
forming a dielectric on the channel layer and extending over the first gate stack and the second gate stack, wherein a hydrogen blocking material layer is buried in a middle of the dielectric and extends over the first gate stack and the second gate stack; and
removing a portion of the dielectric over the second gate stack and a portion of the hydrogen blocking material layer over the second gate stack,
wherein a remaining portion of the hydrogen blocking material layer over the first gate stack is referred to as the first hydrogen blocking layer, and a remaining portion of the dielectric over the second gate stack is referred to as the second lower dielectric film, and wherein a portion of the dielectric over the first gate stack that is covered by the first hydrogen blocking layer is referred to as the first lower dielectric film.

7. The method of claim 1, comprising:
forming a patterned dielectric layer on the channel layer and over the first gate stack and the second gate stack, wherein the patterned dielectric layer includes the first lower dielectric film, the second lower dielectric film, and a dielectric portion on the first hydrogen blocking layer,
wherein the dielectric film further includes an extending dielectric portion on the dielectric portion.

8. The method of claim 1, comprising:
forming a dielectric material on the channel layer;
patterning the dielectric material and the channel layer, thereby forming the first lower dielectric film and a first channel portion on the first gate stack, and forming the second lower dielectric film and a second channel portion on the second gate stack.

9. The method of claim 8, wherein the first hydrogen blocking layer covers a top surface and lateral surfaces of the first lower dielectric film, and the first hydrogen blocking layer covers lateral surfaces of the first channel portion.

10. A method of forming a semiconductor structure, comprising:
forming a transistor having active regions in a substrate; and
forming a memory structure over the substrate and above the transistor, comprising:
forming a first gate electrode and a second gate electrode over the substrate and above the transistor;
forming a first selector layer on the first gate electrode and a second selector layer on the second gate electrode;
forming a patterned dielectric layer on the first selector layer and the second selector layer, wherein the patterned dielectric layer comprises:
a first hydrogen blocking layer on a first lower dielectric film that is on the first selector layer;
a dielectric portion on the first hydrogen blocking layer; and
a second lower dielectric film on the second selector layer;
wherein a top surface of the second lower dielectric film is exposed and lower than a top surface of the first hydrogen blocking layer;
forming a dielectric film on the second lower dielectric film;
forming a second hydrogen blocking layer on the dielectric film over the second selector layer;
forming a second upper dielectric film on the second hydrogen blocking layer;
forming source/drain features on each of the first selector layer and the second selector layer, wherein the transistor is coupled to one of the source/drain features on the first selector layer or the second selector layer; and
forming a memory cell on one of the source/drain features on the first selector layer and the second selector layer.

11. The method of claim 10, wherein after the dielectric film is formed on the second lower dielectric film, a second lower dielectric portion that collectively includes the dielectric film and the second lower dielectric film is thicker than the first lower dielectric film.

12. The method of claim 11, wherein a hydrogen concentration of the second lower dielectric portion is greater than a hydrogen concentration of the first lower dielectric film.

13. The method of claim 10, further comprising:
forming another transistor on the substrate,
wherein the transistor is coupled to one of the source/drain features that are on the first selector layer, and the another transistor is coupled to one of the source/drain features that are on the second selector layer.

14. The method of claim 13, wherein the memory cell is formed on a drain of the source/drain features that are on the first selector layer, and the method further comprises:
forming another memory cell on a drain of the source/drain features that are on the second selector layer,
wherein the transistor and the another transistor supply power to the memory cell and the another memory cell, respectively.

15. The method of claim 10, wherein the first selector layer includes a first high-k gate dielectric layer on the first gate electrode and a first channel layer on the first high-k gate dielectric layer, and
the second selector layer includes a second high-k gate dielectric layer on the second gate electrode and a second channel layer on the second high-k gate dielectric layer,
wherein the second channel layer is separated from the first channel layer.

16. A semiconductor structure, comprising:
a first TFT and a second TFT over a substrate and separated from each other, and each of the first TFT and the second TFT comprising:
a gate stack over the substrate;
a channel layer on the gate stack;
a dielectric layer on the channel layer;
a hydrogen blocking layer buried in a middle of the dielectric layer;
source/drain features formed in the dielectric layer and in contact with the channel layer,
wherein the hydrogen blocking layers of the first TFT and the second TFT are positioned at different levels;
an interconnect structure disposed over the first TFT and the second TFT, wherein the interconnect structure comprises a plurality of metal lines disposed in the plurality of interconnect dielectric layers;
a first memory cell formed on the first TFT and in one of the interconnect dielectric layers, wherein the first memory cell is electrically connected to one of the source/drain features of the first TFT; and
a second memory cell formed on the second TFT and in one of the interconnect dielectric layers, wherein the second memory cell is electrically connected to one of the source/drain features of the second TFT.

17. The semiconductor structure of claim 16, wherein a lower portion of the dielectric layer between the hydrogen blocking layer and the channel layer of the first TFT has a first thickness, a lower portion of the dielectric layer between the hydrogen blocking layer and the channel layer of the second TFT has a second thickness, and the first thickness is different from the second thickness.

18. The semiconductor structure of claim 17, wherein the first thickness is less than the second thickness, and a threshold voltage of the first TFT is higher than a threshold voltage of the second TFT.

19. The semiconductor structure of claim 17, wherein the hydrogen blocking layer of each of the first TFT and the second TFT further covers lateral surfaces of the lower portion of the dielectric layer.

20. The semiconductor structure of claim 16, wherein the first TFT is configured to selectively supply power to the first memory cell, and the second TFT is configured to selectively supply power to the second memory cell.
